(19) United States
(12) Patent Application Publication
(10) Pub. No.: US 2013/0216950 A1
(43) Pub. Date: Aug. 22, 2013

(54) LITHOGRAPHIC PRINTING PLATE PRECURSOR AND PLATE MAKING METHOD USING THE SAME

(71) Applicant: FUJIFILM CORPORATION, (US)

(72) Inventors: Takashi SATO, Yoshida-cho (JP); Junya ABE, Yoshida-cho (JP); Yu IWAI, Yoshida-cho (JP)

(73) Assignee: FUJIFILM CORPORATION, TOKYO (JP)

(21) Appl. No.: 13/852,537

(22) Filed: Mar. 28, 2013

Related U.S. Application Data
(63) Continuation of application No. PCT/JP2011/071007, filed on Sep. 14, 2011.

(30) Foreign Application Priority Data
Sep. 29, 2010 (JP) 2010-220086

(51) Int. Cl. G03F 7/09; G03F 7/26

(52) U.S. Cl. CPC G03F 7/09; G03F 7/26
USPC 430/285.1; 430/302

(57) ABSTRACT

A lithographic printing plate precursor includes a support, an undercoat layer and an image-recording layer in this order, in which by exposing imagewise the image-recording layer with laser and then supplying at least any of printing ink and dampening water on a cylinder of a printing machine, an unexposed area of the image-recording layer can be removed, and the image-recording layer contains (A) a polymerization initiator, (B) a polymerizable compound and (C) a binder polymer, and the undercoat layer contains the copolymer (D1) as defined herein and the copolymer (D2) as defined herein and a weight of the copolymer (D1) is from 5 to 95% based on a total weight of the copolymers (D1) and (D2).

### TECHNICAL FIELD

The present invention relates to a lithographic printing plate precursor and a plate making method using the same, and particularly to a lithographic printing plate precursor suitable for on-press development and a plate making method using the same.

### BACKGROUND ART

With respect to hitherto known lithographic printing plate precursors (hereinafter, also referred to as PS plates), since a step of removing the non-image area by dissolution (development processing) with strong alkali after imagewise exposure is performed, a post-processing step, for example, washing of the printing plate after the development processing with water, treatment of the printing plate after the development processing with a rinse solution containing a surfactant or treatment of the printing plate after the development processing with an oil-desensitizing solution containing gum arabic or a starch derivative, is necessary. The point that such additional wet treatments are indispensable is a large subject of investigation in hitherto known PS plates. Particularly, the consideration for global environment has become a great concern throughout the field of industry in recent years.

From this viewpoint, as one method for eliminating the processing step, a method referred to as on-press development wherein an exposed lithographic printing plate precursor is mounted on a cylinder of a printing machine and the non-image area of the lithographic printing plate precursor is removed by supplying dampening water and ink while rotating the cylinder is known. Specifically, according to the method, the lithographic printing plate precursor is exposed and mounted on a printing machine as it is to complete development processing in a conventional process of printing (see, for example, Patent Document 1). Also, a method is known wherein development is performed using a developer having a pH range lower than a developer used in hitherto known alkali development and after the development step, a post-water washing step and an oil-sensitizing treatment step (gum solution treatment step) are not conducted (see, for example, Patent Documents 2 and 3).

In such a lithographic printing plate precursor of a simple processing type, a support having a surface of high hydrophilicity is used in order to make possible development with a developer having pH lower than a hitherto known developer or dampening water (ordinarily nearly neutral) on a printing machine and as a result, the image area is apt to be removed from the support by dampening water during printing so that sufficient printing durability can not be obtained. On the contrary, when the surface of support renders hydrophobic, ink also adheres on the non-image area during printing to cause printing stain. Thus, it is extremely difficult to achieve a good compatibility between the printing durability and the stain resistance and further improvements are desired.

In view of the above problems, in Patent Document 4, a lithographic printing plate precursor comprising a support having thereon a hydrophilic layer composed of a hydrophilic polymer which contains at least one of a reactive group capable of directly chemically bonding with a surface of the support and a reactive group capable of chemically bonding with a surface of the support through a crosslinked structure and a partial structure having a positive charge and a negative charge and which is chemically boned to the surface of the support and an image-forming layer in this order is proposed and it is described that a lithographic printing plate which is excellent in hydrophilicity of the non-image area and its sustention and also excellent in adhesion property between the image area and the support is obtained.

However, with respect to the lithographic printing plate precursor proposed in Patent Document 4, since the hydrophilic polymer used in the undercoat layer is a copolymer simultaneously containing (1) a repeating unit having a functional group capable of interacting with a surface of the support, (2) a repeating unit having a repeating unit having a hydrophilic group for exhibiting hydrophilicity in the non-image area and (3) a repeating unit having an ethylenically unsaturated bond for adhering the image area, when (1) and (2) are increased in order to improvement in stain resistance and printing durability, (3) is decreased and thus a disadvantage occurs in that adhesion property between the support and the undercoat layer is lost to cause deterioration of both the printing durability and the stain resistance.

### PRIOR ART DOCUMENT

### Patent Document

Patent Document 1: JP-A-2005-125749
Patent Document 2: EP-A-1751625
Patent Document 3: EP-A-1868036
Patent Document 4: JP-A-2008-213177

### DISCLOSURE OF THE INVENTION

### Problems that the Invention is to Solve

Therefore, an object of the present invention is to provide a lithographic printing plate precursor which is capable of conducting direct plate making based on digital data, for example, from a computer, by image-recording using a solid laser or semiconductor laser emitting an ultraviolet ray or visible light, particularly, a lithographic printing plate precursor which can be developed on a printing machine, is excellent in development property, has high sensitivity and can provide a lithographic printing plate exhibiting high printing durability and good stain resistance (including stain resistance after the lapse of time), and a plate making method using the same.

### Means for Solving the Problems

As a result of the intensive investigations, the inventors have found that the above-described object can be achieved by using a lithographic printing plate precursor described below.

Specifically, the present invention includes the following items.

(1) A lithographic printing plate precursor comprising a support, an undercoat layer and an image-recording layer in this order in which by exposing imagewise the image-recording layer with laser and then supplying at least any of printing ink and dampening water on a cylinder of a printing machine, an unexposed area of the image-recording layer can be removed, wherein the image-recording layer contains (A) a polymerization initiator, (B) a polymerizable compound and (C) a binder polymer, and the undercoat layer contains a copolymer (D1) containing (a1) a repeating unit having a zwitterionic structure and (a2) a repeating unit having a structure capable of interacting with a surface of the support and a copolymer (D2) containing (a3) a repeating unit having an ethylenically unsaturated bond and (a2) a repeating unit having a structure capable of interacting with a surface of the support and a weight of the copolymer (D1) is from 5 to 95% based on a total weight of the copolymers (D1) and (D2).
(2) The lithographic printing plate precursor as described in (1) above, wherein the zwitterionic structure is a structure represented by formula (i), formula (ii) or formula (iii) shown below.

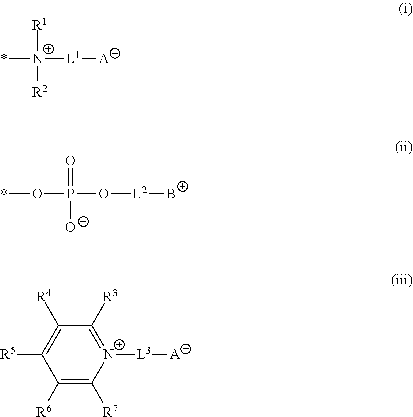

In formula (i), formula (ii) and formula (iii), R¹ and R² each independently represents a hydrogen atom, an alkyl group, an alkenyl group, an alkynyl group, an aryl group or a heterocyclic group, or R¹ and R² may be combined with each other to form a ring structure, R³ to R⁷ each independently represents a hydrogen atom or a substituent, provided that at least one of R³ to R⁷ represents a site connecting to a main chain or side chain of the polymer, L¹, L² and L³ each independently represents a connecting group, A represents a group having an anion, B represents a group having a cation, and * represents a site connecting to a main chain or side chain of the polymer.

(3) The lithographic printing plate precursor as described in (2) above, wherein in formula (i), formula (ii) or formula (iii) A represents a carboxylate, a sulfonate, a phosphonate or a phosphinate, and B represents an ammonium, a phosphonium, an iodonium or a sulfonium.
(4) The lithographic printing plate precursor as described in any one of (1) to (3) above, wherein the structure capable of interacting with a surface of the support in at least any of the copolymer (D1) and the copolymer (D2) is a structure having a carboxylic acid group or a salt thereof, a sulfonic acid group or a salt thereof, a phosphoric ester group or a salt thereof, or a phosphoric acid group or a salt thereof.
(5) The lithographic printing plate precursor as described in any one of (1) to (4) above, wherein the copolymer (D1) further contains (a4) a repeating unit having a hydrophilic group other than the zwitterionic structure.
(6) The lithographic printing plate precursor as described in (5) above, wherein the hydrophilic group in the repeating unit (a4) is at least one of an alkylene oxide group, a sulfonic acid group, a sulfonate group and a sulfonamido group.
(7) The lithographic printing plate precursor as described in any one of (1) to (6) above, wherein the binder polymer (C) is a polymer having an alkylene oxide chain as a hydrophilic group.
(8) The lithographic printing plate precursor as described in any one of (1) to (7) above, wherein the binder polymer (C) is a straight-chain polymer or a branched polymer having a branch point.
(9) The lithographic printing plate precursor as described in any one of (1) to (8) above, which has a protective layer containing at least one kind of water-soluble resin as an uppermost layer.
(10) A plate making method of performing on-press development processing by a method comprising exposing imagewise the lithographic printing plate precursor as described in any one of (1) to (9) above, mounting the exposed lithographic printing plate precursor on a printing machine and supplying at least any of printing ink and dampening water or a method comprising mounting the lithographic printing plate precursor as described in any one of (1) to (9) above on a printing machine, exposing imagewise the lithographic printing plate precursor and supplying at least any of printing ink and dampening water.

The functional mechanism according to the invention is presumed as follows.

Specifically, by incorporating the copolymer (D1) containing (a1) a repeating unit having a zwitterionic structure and (a2) a repeating unit having a functional group capable of interacting with a surface of the support into an undercoat layer, the hydrophilicity of the support is extremely high even after on-press development and as a result, a lithographic printing plate excellent in the stain resistance is obtained. Also, by incorporating the copolymer (D2) containing the repeating unit (a2) and (a3) a repeating unit having an ethylenically unsaturated bond into an undercoat layer, the undercoat layer and the image-recording layer are crosslinked in the exposed area to increase the adhesion property of the image area to the substrate and as a result, a lithographic printing plate excellent in the printing durability is obtained.

### Advantage of the Invention

According to the present invention, a lithographic printing plate precursor which exhibits high productivity capable of conducting a so-called direct plate making wherein the plate making is directly conducted based on digital signals, for example, from a computer using various, particularly, a lithographic printing plate precursor which can be developed on a printing machine, has high sensitivity and can provide a lithographic printing plate exhibiting good printing durability and good stain resistance (including stain resistance after the lapse of time) and a plate making method using the same can be provided.

### MODE FOR CARRYING OUT THE INVENTION

In the specification, with respect to the description of a group in a compound represented by a formula, when the group is not indicated whether substituted or unsubstituted, unless otherwise indicated specifically, the group includes not only the unsubstituted group but also the substituted group, if the group is able to have a substituent. For example, the description “R represents an alkyl group, an aryl group or a heterocyclic group” in a formula means that “R represents an unsubstituted alkyl group, a substituted alkyl group, an unsubstituted aryl group, a substituted aryl group, an unsubstituted heterocyclic group or a substituted heterocyclic group”.

The lithographic printing plate precursor according to the invention will be described in detail below.

The lithographic printing plate precursor which can be used in the invention is characterized by comprising a support, an undercoat layer and an image-recording layer in this order in which by exposing imagewise the image-recording layer with laser and then supplying at least any of printing ink and dampening water on a cylinder of a printing machine, an unexposed area of the image-recording layer can be removed, wherein the image-recording layer contains (A) a polymerization initiator, (B) a polymerizable compound and (C) a binder polymer, and the undercoat layer contains a copolymer (D1) (hereinafter abbreviated as a specific polymer compound (D1)) containing (a1) a repeating unit having a zwitterionic structure and (a2) a repeating unit having a structure capable of interacting with a surface of the support and a copolymer (D2) (hereinafter abbreviated as a specific polymer compound (D2)) containing (a3) a repeating unit having an ethylenically unsaturated bond and (a2) a repeating unit having a structure capable of interacting with a surface of the support and a weight of the copolymer (D1) is from 5 to 95% based on a total weight of the copolymers (D1) and (D2). The undercoat layer described above is also referred to as an intermediate layer in some cases.

The components of respective layers are described in more detail below.

### [Undercoat Layer]

### <Specific Polymer Compound>

The specific polymer compound (D1) which can be used in the lithographic printing plate precursor according to the invention is a copolymer containing (a1) a repeating unit having a zwitterionic structure and (a2) a repeating unit having a functional group capable of interacting with a surface of the support.

The specific polymer compound (D1) is described in detail below.

First, the repeating unit having a zwitterionic structure is described below.

The zwitterionic structure according to the invention is a structure which has a positive charge and a negative charge and is neutral as a whole.

The zwitterionic structure preferably includes groups represented by formulae (i) to (iii) shown below. The zwitterionic structure is preferably a group represented by formulae (i) or (ii). From the standpoint of printing durability, the zwitterionic structure is more preferably the group represented by formula (i).

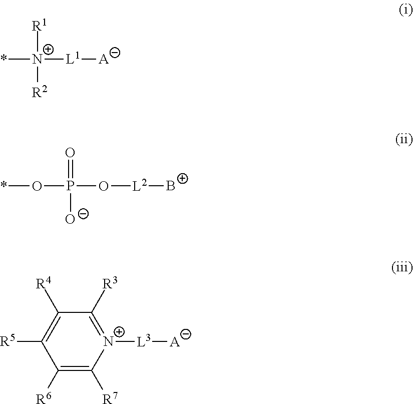

In formulae (i), (ii) and (iii), R¹ and R² each independently represents a hydrogen atom, an alkyl group, an alkenyl group, an alkynyl group, an aryl group or a heterocyclic group, or R¹ and R² may be combined with each other to form a ring structure. R³ to R⁷ each independently represents a hydrogen atom or a substituent (preferably having from 1 to 30 carbon atoms), provided that at least one of R³ to R⁷ represents a site connecting to a main chain or side chain of the polymer. L¹, L² and L³ each independently represents a connecting group.

A represents a structure having an anion (for example, a carboxylate, a sulfonate, a phosphonate or a phosphinate), B represents a structure having a cation (for example, an ammonium, a phosphonium, an iodonium or a sulfonium).

* represents a site connecting to a main chain or side chain of the polymer.

At least one of R³ to R⁷ of the connecting sites may be connected to the main chain or side chain of the polymer through the substituent represented by any one of R³ to R⁷ or directly by a single bond.

In formula (i), A preferably represents a carboxylate, a sulfonate, a phosphonate or a phosphinate. Specifically, it includes anions having the structure shown below. Among them, a carboxylate group or a sulfonate group is preferred from the standpoint of stain resistance.

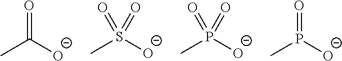

L¹ is preferably a connecting group selected from the group consisting of —CO—, —O—, —NH—, a divalent aliphatic group, a divalent aromatic group and a combination thereof and a number of carbon atoms of the connecting group which includes a number of carbon atoms contained in substituents described below which may be present is preferably 30 or less. Specific examples of the connecting group include an alkylene group (preferably having from 1 to 20 carbon atoms, more preferably having from 1 to 10 carbon atoms) and an arylene group (preferably having from 5 to 15 carbon atoms, more preferably having from 6 to 10 carbon atoms), for example, a phenylene group or a xylylene group. Form the standpoint of stain resistance, L¹ is preferably a straight-chain alkylene group having from 3 to 5 carbon atoms, more preferably a straight-chain alkylene group having 4 to 5 carbon atoms, and most preferably a straight-chain alkylene group having 4 carbon atoms.

Specific examples of L¹ include the connecting groups set forth below.

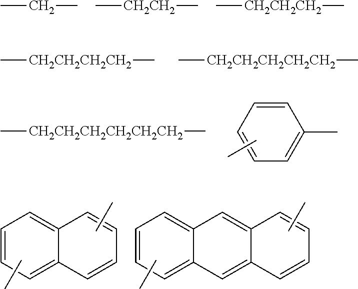

The connecting group may further have a substituent. Examples of the substituent include those same as the substituent which R¹ or R² may have described below.

In formula (i), R¹ and R² each independently represents a hydrogen atom, an alkyl group, an alkenyl group, an alkynyl group, an aryl group or a heterocyclic group, or R¹ and R² may be combined with each other to form a ring structure. The ring structure may contain a hetero atom, for example, an oxygen atom and is preferably a 5-membered to 10-membered ring and more preferably a 5-membered or 6-membered ring. A number of carbon atoms of the group represented by R¹ or R² which includes a number of carbon atoms contained in substituents described below which may be present is preferably from 1 to 30, more preferably from 1 to 20, particularly preferably from 1 to 15, and most preferably from 1 to 8.

Examples of the alkyl group include a methyl group, an ethyl group, a propyl group, an octyl group, an isopropyl group, a tert-butyl group, an isopentyl group, a 2-ethylhexyl group, a 2-methylhexyl group and a cyclopentyl group.

Examples of the alkenyl group include a vinyl group, an allyl group, a prenyl group, geranyl group and an oleyl group.

Examples of the alkynyl group include an ethynyl group, a propargyl group and a trimethylsilylethynyl group.

Examples of the aryl group include a phenyl group, a 1-naphtyl group and a 2-naphthyl group. Examples of the heterocyclic group include a furanyl group, a thiophenyl group and a pyridinyl group.

These groups may further have a substituent. Examples of the substituent include a halogen atom (e.g., F, Cl, Br or I), a hydroxy group, a carboxyl group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, a monoarylamino group and a diarylamino group.

As R¹ or R², a hydrogen atom, a methyl group or an ethyl group is exemplified as a particularly preferred example from the standpoint of the effects and ease in availability.

In formula (ii), B represents a group having a cation and preferably a group having an ammonium, a phosphonium, an iodonium or a sulfonium. The group having an ammonium or phosphonium is more preferred and the group having an ammonium is particularly preferable. Examples of the group having a cation include a trimethylammonio group, a triethylammonio group, a tributylammonio group, a benzyldimethylammonio group, a diethylhexylammonio group, a (2-hydroxyethyl)dimethylammonio group, a pyridinio group, an N-methylimidazolio group, an N-acridinio group, a trimethylphosphonio group, a triethylphosphonio group and a triphenylphosphonio group.

In formula (ii), L² is preferably a connecting group selected from the group consisting of —CO—, —O—, —NH—, a divalent aliphatic group, a divalent aromatic group and a combination thereof similar to L¹ in formula (i) and a number of carbon atoms of the connecting group which includes a number of carbon atoms contained in substituents which may be present is preferably 30 or less. Specific examples of the connecting group include an alkylene group (preferably having from 1 to 20 carbon atoms, more preferably having from 1 to 10 carbon atoms) and an arylene group (preferably having from 5 to 15 carbon atoms, more preferably having from 6 to 10 carbon atoms), for example, a phenylene group or a xylylene group. Form the standpoint of stain resistance, L² is preferably a straight-chain alkylene group having from 3 to 5 carbon atoms, more preferably a straight-chain alkylene group having 4 to 5 carbon atoms, and most preferably a straight-chain alkylene group having 4 carbon atoms. Examples of the substituent which L² may have include the substituents as described for L¹.

Specific examples of L² include the connecting groups as described for the specific examples of L¹.

In formula (iii), A preferably represents a carboxylate, a sulfonate, a phosphonate or a phosphinate. Specifically, an anion having the structure described above similar to A in formula (i). Among them, a carboxylate group or a sulfonate group is more preferred from the standpoint of stain resistance.

In formula (iii), L³ is preferably a connecting group selected from the group consisting of —CO—, —O—, —NH—, a divalent aliphatic group, a divalent aromatic group and a combination thereof similar to L¹ in formula (i) and a number of carbon atoms of the connecting group which includes a number of carbon atoms contained in substituents which may be present is preferably 30 or less. Specific examples of the connecting group include an alkylene group (preferably having from 1 to 20 carbon atoms, more preferably having from 1 to 10 carbon atoms) and an arylene group (preferably having from 5 to 15 carbon atoms, more preferably having from 6 to 10 carbon atoms), for example, a phenylene group or a xylylene group. Form the standpoint of stain resistance, L³ is preferably a straight-chain alkylene group having from 3 to 5 carbon atoms, more preferably a straight-chain alkylene group having 4 to 5 carbon atoms, and most preferably a straight-chain alkylene group having 4 carbon atoms. Examples of the substituent which L³ may have include the substituents as described for L¹.

Specific examples of L³ include the connecting groups as described for the specific examples of L¹.

In formula (iii), R³ to R⁷ each independently represents a hydrogen atom or a substituent. The substituent represented by any one of R³ to R⁷ includes, for example, a halogen atom, an alkyl group (including a cycloalkyl group and a bicycloalkyl group), an alkenyl group (including a cycloalkenyl group and a bicycloalkenyl group), an alkynyl group, an aryl group, a heterocyclic group, a cyano group, a hydroxy group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an aniline group), an acylamino group, an aminocarbonylamino group, an alkoxycarbonylamino group, an aryloxycarbonylamino group, a sulfamoylamino group, an alkyl or aryl sulfonylamino group, a mercapto group, an alkylthio group, an arylthio group, a heterocyclic thio group, a sulfamoyl group, a sulfo group, an alkyl or aryl sulfinyl group, an alkyl or aryl sulfonyl group, an acyl group, an aryloxycarbonyl group, an alkoxycarbonyl group, a carbamoyl group, an aryl or heterocyclic azo group, an imido group, a phosphino group, a phosphinyl group, a phosphinyloxy group, a phosphinylamino group and a silyl group.

More specifically, the substituent includes a halogen atom (for example, a chlorine atom, a bromine atom or an iodine atom), an alkyl group [representing a straight-chain, branched or cyclic, substituted or unsubstituted alkyl group and including an alkyl group (preferably a substituted or unsubstituted alkyl group having from 1 to 30 carbon atoms, for example, methyl, ethyl, n-propyl, isopropyl, tert-butyl, n-octyl, eucosyl, 2-chloroethyl, 2-cyanoethyl or 2-ethylhexyl), a cycloalkyl group (preferably a substituted or unsubstituted cycloalkyl group having from 3 to 30 carbon atoms, for example, cyclohexyl, cyclopentyl or 4-n-dodecylcyclohexyl), a bicycloalkyl group (preferably a substituted or unsubstituted bicycloalkyl group having from 5 to 30 carbon atoms, that is, a monovalent group formed by eliminating one hydrogen atom from a bicycloalkane having from 5 to 30 carbon atoms, for example, bicyclo[1,2,2]heptan-2-yl or bicyclo[2,2,2]octan-3-yl) and a cycloalkyl group having more cyclic structures, for example, a tricycloalkyl group; an alkyl group included in the substituent described hereinafter (for example, the alkyl group in the alkylthio group) also having the same meaning as described above], an alkenyl group [representing a straight-chain, branched or cyclic, substituted or unsubstituted alkenyl group and including an alkenyl group (preferably a substituted or unsubstituted alkenyl group having from 2 to 30 carbon atoms, for example, vinyl, allyl, prenyl, geranyl or oleyl), a cycloalkenyl group (preferably a substituted or unsubstituted cycloalkenyl group having from 3 to 30 carbon atoms, that is, a monovalent group formed by eliminating one hydrogen atom from a cycloalkene having from 3 to 30 carbon atoms, for example, 2-cyclopenten-1-yl or 2-cyclohexen-1-yl), and a bicycloalkenyl group (preferably a substituted or unsubstituted bicycloalkenyl group having from 5 to 30 carbon atoms, that is, a monovalent group formed by eliminating one hydrogen atom from a bicycloalkene having one double bond, for example, bicyclo[2,2,1]hept-2-en-1-yl or bicyclo[2,2,2]oct-2-en-4-yl)], an alkynyl group (preferably a substituted or unsubstituted alkynyl group having from 2 to 30 carbon atoms, for example, ethynyl, propargyl or trimethylsilylethynyl), an aryl group (preferably a substituted or unsubstituted aryl group having from 6 to 30 carbon atoms, for example, phenyl, p-tolyl, naphthyl, m-chlorophenyl or o-hexadecanoylaminophenyl), a heterocyclic group (preferably a monovalent group formed by eliminating one hydrogen atom from a 5-membered or 6-membered, substituted or unsubstituted, aromatic or non-aromatic heterocyclic compound, more preferably a 5-membered or 6-membered aromatic heterocyclic group having from 5 to 30 carbon atoms, for example, 2-furyl, 2-thienyl, 2-pyrimidinyl or 2-benzothiazolyl), a cyano group, a hydroxy group, a nitro group, a carboxyl group, an alkoxy group (preferably a substituted or unsubstituted alkoxy group having from 1 to 30 carbon atoms, for example, methoxy, ethoxy, isopropoxy, tert-butoxy, n-octyloxy or 2-methoxyethoxy), an aryloxy group (preferably a substituted or unsubstituted aryloxy group having from 6 to 30 carbon atoms, for example, phenoxy, 2-methyphenoxy, 4-tert-butylphenoxy, 3-nitrophenoxy or 2-tetradecanoylaminophenoxy), a silyloxy group (preferably a silyloxy group having from 3 to 20 carbon atoms, for example, trimethylsilyloxy or tert-butyldimethylsilyloxy), a heterocyclic oxy group (preferably a substituted or unsubstituted heterocyclic oxy group having from 2 to 30 carbon atoms, for example, 1-phenyltetrazol-5-oxy or 2-tetrahydropyranyloxy), an acyloxy group (preferably a formyloxy group, a substituted or unsubstituted alkylcarbonyloxy group having from 2 to 30 carbon atoms or a substituted or unsubstituted arylcarbonyloxy group having from 6 to 30 carbon atoms, for example, formyloxy, acetyloxy, pivaloyloxy, stearoyloxy, benzoyloxy or p-methoxyphenylcarbonyloxy), a carbamoyloxy group (preferably a substituted or unsubstituted carbamoyloxy group having from 1 to 30 carbon atoms, for example, N,N-dimethylcarbamoyloxy, N,N-diethylcarbamoyloxy, morpholinocarbonyloxy, N,N-di-n-octylaminocarbonyloxy or N-n-octylcarbamoyloxy), an alkoxycarbonyloxy group (preferably a substituted or unsubstituted alkoxycarbonyloxy group having from 2 to 30 carbon atoms, for example, methoxycarbonyloxy, ethoxycarbonyloxy, tert-butoxycarbonyloxy or n-octyloxycarbonyloxy), an aryloxycarbonyloxy group (preferably a substituted or unsubstituted aryloxycarbonyloxy group having from 7 to 30 carbon atoms, for example, phenoxycarbonyloxy, p-methoxyphenoxycarbonyloxy or p-n-hexadecyloxyphenoxycarbonyloxy), an amino group (preferably an amino group, a substituted or unsubstituted alkylamino group having from 1 to 30 carbon atoms or a substituted or unsubstituted anilino group having from 6 to 30 carbon atoms, for example, amino, methylamino, dimethylamino, anilino, N-methylanilino or diphenylamino), an acylamino group (preferably a formylamino group, a substituted or unsubstituted alkylcarbonylamino group having from 1 to 30 carbon atoms or a substituted or unsubstituted arylcarbonylamino group having from 6 to 30 carbon atoms, for example, formylamino, acetylamino, pivaloylamino, lauroylamino, benzoylamino or 3,4,5-tri-n-octyloxyphenylcarbonylamino), an aminocarbonylamino group (preferably a substituted or unsubstituted aminocarbonylamino group having from 1 to 30 carbon atoms, for example, carbamoylamino, N,N-dimethylaminocarbonylamino, N,N-diethylaminocarbonylamino or morpholinocarbonylamino), an alkoxycarbonylamino group (preferably a substituted or unsubstituted alkoxycarbonylamino group having from 2 to 30 carbon atoms, for example, methoxycarbonylamino, ethoxycarbonylamino, tert-butoxycarbonylamino, n-octadecyloxycarbonylamino or N-methylmethoxycarbonylamino), an aryloxycarbonylamino group (preferably a substituted or unsubstituted aryloxycarbonylamino group having from 7 to 30 carbon atoms, for example, phenoxycarbonylamino, p-chlorophenoxycarbonylamino or m-(n-octyloxy)phenoxycarbonylamino), a sulfamoylamino group (preferably a substituted or unsubstituted sulfamoylamino group having from 0 to 30 carbon atoms, for example, sulfamoylamino, N,N-dimethylaminosulfonylamino or N-n-octylaminosulfonylamino), an alkyl or aryl sulfonylamino group (preferably a substituted or unsubstituted alkylsulfonylamino group having from 1 to 30 carbon atoms or a substituted or unsubstituted arylsulfonylamino group having from 6 to 30 carbon atoms, for example, methylsulfonylamino, butylsulfonylamino, phenylsulfonylamino, 2,3,5-trichlorophenylsulfonylamino or p-methylphenylsulfonylamino), a mercapto group, an alkylthio group (preferably a substituted or unsubstituted alkylthio group having from 1 to 30 carbon atoms, for example, methylthio, ethylthio or n-hexadecylthio), an arylthio group (preferably a substituted or unsubstituted arylthio group having from 6 to 30 carbon atoms, for example, phenylthio, p-chlorophenylthio or m-methoxyphenylthio), a heterocyclic thio group (preferably a substituted or unsubstituted heterocyclic thio group having from 2 to 30 carbon atoms, for example, 2-benzothiazolylthio or 1-phenyltetrazol-5-ylthio), a sulfamoyl group (preferably a substituted or unsubstituted sulfamoyl group having from 0 to 30 carbon atoms, for example, N-ethylsulfamoyl, N-(3-dodecyloxypropyl)sulfamoyl, N,N-dimethylsulfamoyl, N-acetylsulfamoyl, N-benzoylsulfamoyl or N—(N′-phenylcarbamoyl)sulfamoyl), a sulfo group, an alkyl or aryl sulfinyl group (preferably a substituted or unsubstituted alkylsulfinyl group having from 1 to 30 carbon atoms or a substituted or unsubstituted arylsulfinyl group having from 6 to 30 carbon atoms, for example, methylsulfinyl, ethylsulfinyl, phenylsulfinyl or p-methylphenylsulfinyl), an alkyl or aryl sulfonyl group (preferably a substituted or unsubstituted alkylsulfonyl group having from 1 to 30 carbon atoms or a substituted or unsubstituted arylsulfonyl group having from 6 to 30 carbon atoms, for example, methylsulfonyl, ethylsulfonyl, phenylsulfonyl or p-methylphenylsulfonyl), an acyl group (preferably a formyl group, a substituted or unsubstituted alkylcarbonyl group having from 2 to 30 carbon atoms, a substituted or unsubstituted arylcarbonyl group having from 7 to 30 carbon atoms or a substituted or unsubstituted heterocyclic carbonyl group having from 4 to 30 carbon atoms wherein the hetero ring is connected to the carbonyl group via a carbon atom, for example, acetyl, pivaloyl, 2-chloroacetyl, stearoyl, benzoyl, p-n-octyloxyphenylcarbonyl, 2-pyridylcarbonyl or 2-furylcarbonyl), an aryloxycarbonyl group (preferably a substituted or unsubstituted aryloxycarbonyl group having from 7 to 30 carbon atoms, for example, phenoxycarbonyl, o-chlorophenoxycarbonyl, m-nitrophenoxycarbonyl or p-tert-butylphenoxycarbonyl), an alkoxycarbonyl group (preferably a substituted or unsubstituted alkoxycarbonyl group having from 2 to 30 carbon atoms, for example, methoxycarbonyl, ethoxycarbonyl, tert-butoxycarbonyl or n-octadecyloxycarbonyl), a carbamoyl group (preferably a substituted or unsubstituted carbamoyl group having from 1 to 30 carbon atoms, for example, carbamoyl, N-methylcarbamoyl, N,N-dimethylcarbamoyl, N,N-di-n-octylcarbamoyl or N-(methylsulfonyl)carbamoyl), an aryl or heterocyclic azo group (preferably a substituted or unsubstituted aryl azo group having from 6 to 30 carbon atoms or a substituted or unsubstituted heterocyclic azo group having from 3 to 30 carbon atoms, for example, phenylazo, p-chlorophenylazo or 5-ethylthio-1,3,4-tiadiazol-2-ylazo), an imido group (preferably N-succinimide or N-phthalimido), a phosphino group (preferably a substituted or unsubstituted phosphino group having from 2 to 30 carbon atoms, for example, dimethylphosphino, diphenylphosphino or methylphenoxyphosphino), a phosphinyl group (preferably a substituted or unsubstituted phosphinyl group having from 2 to 30 carbon atoms, for example, phosphinyl, dioctyloxyphosphinyl or diethoxyphosphinyl), a phosphinyloxy group (preferably a substituted or unsubstituted phosphinyloxy group having from 2 to 30 carbon atoms, for example, diphenoxyphosphinyloxy or dioctyloxyphosphinyloxy), a phosphinylamino group (preferably a substituted or unsubstituted phosphinylamino group having from 2 to 30 carbon atoms, for example, dimethoxyphosphinylamino or dimethylaminophosphinylamino), and a silyl group (preferably a substituted or unsubstituted silyl group having from 3 to 30 carbon atoms, for example, trimethylsilyl, tert-butyldimethylsilyl or phenyldimethylsilyl).

Of the substituents described above, in those having a hydrogen atom, the hydrogen atom may be substituted with the substituent described above. Examples of such a functional group include an alkylcarbonylaminosulfonyl group, an arylcarbonylaminosulfonyl group, an alkylsulfonylaminocarbonyl group and an arylsulfonylaminocarbonyl group. Specific examples thereof include methylsulfonylaminocarbonyl, p-methylphenylsulfonylaminocarbonyl, acetylaminosulfonyl and benzoylaminosulfonyl.

It is particularly preferred that the specific polymer compound (D1) has a cation and an anion of the zwitterionic structure in the position corresponding to a side chain of polymer in the repeating unit.

In the invention, specifically, the repeating unit having a zwitterionic structure is preferably represented by formula (A1) shown below.

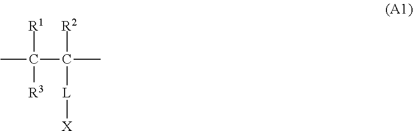

In formula (A1), R¹ to R³ each independently represents a hydrogen atom, an alkyl group having from 1 to 6 carbon atoms or a halogen atom. L represents a single bond or a divalent connecting group selected from the group consisting of —CO—, —O—, —NH—, a divalent aliphatic group, a divalent aromatic group and a combination thereof.

Specific examples of the combination of groups represented by L are set forth below. In each of the specific examples shown below, the left side connects to the main chain and the right side connects to X.

L1: —CO—O-divalent aliphatic group-

L2: —CO—O-divalent aromatic group-

L3: —CO—NH-divalent aliphatic group-

L4: —CO—NH-divalent aromatic group-

L5: —CO-divalent aliphatic group-

L6: —CO-divalent aromatic group-

L7: —CO-divalent aliphatic group-CO—O-divalent aliphatic group-

L8: —CO-divalent aliphatic group-O—CO-divalent aliphatic group-

L9: —CO-divalent aromatic group-CO—O-divalent aliphatic group-

L10: —CO-divalent aromatic group-O—CO-divalent aliphatic group-

L11: —CO-divalent aliphatic group-CO—O-divalent aromatic group-

L12: —CO-divalent aliphatic group-O—CO-divalent aromatic group-

L13: —CO-divalent aromatic group-CO—O-divalent aromatic group-

L14: —CO-divalent aromatic group-O—CO-divalent aromatic group-

L15: —CO—O-divalent aromatic group-O—CO—NH-divalent aliphatic group-

L16: —CO—O-divalent aliphatic group-O—CO—NH-divalent aliphatic group-

L17: —CO—NH—

L18: —CO—O—

The divalent aliphatic group includes an alkylene group, a substituted alkylene group, an alkenylene group, a substituted alkenylene group, an alkinylene group, a substituted alkinylene group and a polyalkyleneoxy group. Among them, an alkylene group, a substituted alkylene group, an alkenylene group and a substituted alkenylene group are preferred, and an alkylene group and a substituted alkylene group are more preferred.

Of the divalent aliphatic groups, a chain structure is preferred than a cyclic structure, and further a straight-chain structure is preferred than a branched structure. A number of carbon atoms included in the divalent aliphatic group is preferably from 1 to 20, more preferably from 1 to 15, still more preferably from 1 to 12, yet still more preferably from 1 to 10, and most preferably from 1 to 8.

Examples of the substituent for the divalent aliphatic group include a halogen atom (e.g., F, Cl, Br or I), a hydroxy group, a carboxyl group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, an acylamino group and a diarylamino group.

The divalent aromatic group includes an arylene group and a substituted arylene group. It preferably includes a phenylene group, a substituted phenylene group, a naphthylene group and a substituted naphthylene group.

Examples of the substituent for the divalent aromatic group include an alkyl group in addition to the substituents described for the divalent aliphatic group described above.

Of L1 to L18 described above, L1 to L4, L17 and L18 are preferred.

L is preferably a single bond, —CO—, —O—, —NH—, a divalent aliphatic group, a divalent aromatic group or any one of L1 to L4, L17 and L18.

In formula (A1), X represents a zwitterionic structure. X is preferably the group represented by formula (i), (ii) or (iii) described above and preferred embodiments are also same as those described in formulae (i), (ii) and (iii).

The content of the repeating unit (a1) having a zwitterionic structure in the specific polymer compound (D1) according to the invention is preferably from 1 to 99% by mole, more preferably from 3 to 80% by mole, still more preferably from 5 to 70% by mole in view of the stain resistance, and most preferably from 5 to 50% by mole considering also the printing durability.

Now, the repeating unit having a functional group capable of interacting with a surface of the support is described below.

The functional group capable of interacting with a surface of the support includes, for example, a group capable of undergoing interaction, for example, forming an ionic bond or a hydrogen bond or undergoing polar interaction or van der Waals interaction, with metal, a metal oxide, a hydroxy group or the like present on the support subjected to anodizing treatment or hydrophilizing treatment is exemplified.

Specific examples of the functional group capable of interacting with a surface of the support are set forth below.

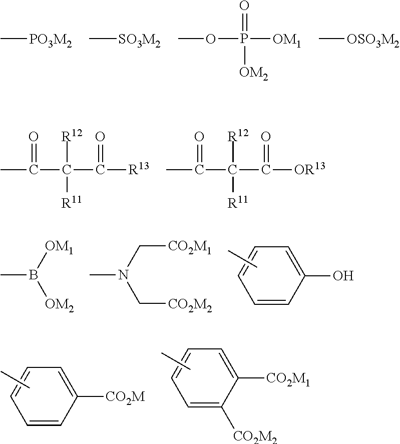

In the above-formulae, R¹¹ to R¹³ each independently represents a hydrogen atom, an alkyl group, an aryl group, an alkynyl group or an alkenyl group, M, M₁ and M₂ each independently represents a hydrogen atom, a metal atom or an ammonium group.

From the standpoint of the stain resistance and printing durability, the functional group capable of interacting with a surface of the support is preferably a carboxylic acid group or a salt thereof, a sulfonic acid group or a salt thereof, a phosphoric acid ester group or a salt thereof or a phosphonic acid group or a salt thereof. In view of further improvement in the stain resistance, a phosphoric acid ester group or a salt thereof or a phosphonic acid group or a salt thereof is more preferred.

In the invention, specifically, the repeating unit having a functional group capable of interacting with a surface of the support is preferably represented by formula (A2) shown below.

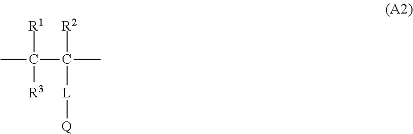

In formula (A2), R¹ to R³ each independently represents a hydrogen atom, an alkyl group having from 1 to 6 carbon atoms or a halogen atom.

L represents a single bond or a divalent connecting group selected from the group consisting of —CO—, —O—, —NH—, a divalent aliphatic group, a divalent aromatic group and a combination thereof.

Specific examples of the combination of groups represented by L include those described in formula (A1). L is preferably a single bond, —CO—, —O—, —NH—, a divalent aliphatic group, a divalent aromatic group or any one of L1 to L4, L17 and L18, and most preferably a single bond.

Q represents a functional group capable of interacting with a surface of the support and preferred embodiments are same as those described above.

The content of the repeating unit (a2) having a functional group capable of interacting with a surface of the support in the specific polymer compound (D1) according to the invention is preferably from 1 to 99% by mole, more preferably from 10 to 90% by mole, and most preferably from 30 to 90% by mole in view of the stain resistance and printing durability.

In view of the stain resistance and printing durability, as to the specific polymer compound (D1) according to the invention, a combination where the zwitterionic structure is the group represented by formula (i) or (ii) and the functional group capable of interacting with a surface of the support is a phosphoric acid ester group or a salt thereof or a phosphonic acid group or a salt thereof is preferred.

Although the specific polymer compound (D1) according to the invention is able to be synthesized by any hitherto known method, a radical polymerization method is preferably used for the synthesis thereof. Ordinary radical polymerization methods are described, for example, in Shin Kobunshi Jikkengaku 3, Kobunshi no Gosei to Hanno 1, edited by The Society of Polymer Science, Japan, (Kyoritsu Shuppan Co., Ltd.), Shin Jikken Kagaku Koza 19, Kobunshi Kagaku (I), edited by The Chemical Society of Japan, (Maruzen Co., Ltd.) and Busshitsu Kogaku Koza, Kobunshi Gosei Kagaku, (Tokyo Denki University Press) and these methods can be applied.

Further, the specific polymer compound (D1) may be a copolymer containing a repeating unit (hereinafter, also simply referred to as other repeating unit) other than (a1) the repeating unit having a zwitterionic structure and (a2) the repeating unit having a functional group capable of interacting with a surface of the support.

The other repeating unit constituting the specific polymer compound according to the invention is preferably a repeating unit represented by formula (A3) shown below.

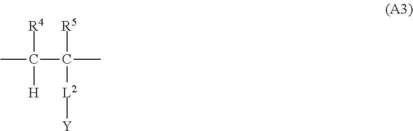

In formula (3A), R⁴ and R⁵ each independently represents a hydrogen atom or a substituent having from 1 to 30 carbon atoms, L² represents a single bond or an organic connecting group, and

Y represents a substituent having from 1 to 30 carbon atoms. In particular, L² is preferably an ester group or an amido group. Y is preferably a structure having a hydrophilic group described in JP-A-2006-264051, specifically, more preferably an alkylene oxide group, a sulfonic acid group, a sulfonate group or a sulfonamido group, and most preferably an alkylene oxide group.

R⁴ and R⁵ each particularly preferably represents a hydrogen atom, a methyl group or an ethyl group in view of the effects and ease in availability.

The other repeating unit is contained preferably in an amount from 0 to 60% by mole, more preferably from 0 to 50% by mole, particularly preferably from 0 to 40% by mole, in the specific polymer compound (D1) as a copolymerization component for (a1) the repeating unit having a zwitterionic structure and (a2) the repeating unit having a functional group capable of interacting with a surface of the support.

The weight average molecular weight (Mw) of the specific polymer compound (D1) according to the invention can be appropriately set according to performance design of the lithographic printing plate precursor. The Mw is preferably from 2,000 to 1,000,000, more preferably from 2,000 to 40,000 in view of the printing durability and stain resistance.

Specific examples of the specific polymer compound (D1) are set forth below together with the Mw thereof, but the invention should not be construed as being limited thereto. The composition ratio in the polymer structure is indicated by a molar percentage.

| | | |
|---|---|---|
| (1) | 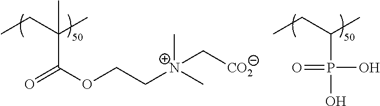 | Mw: 20,000 |
| (2) | 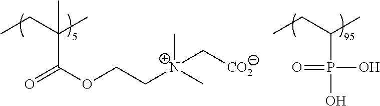 | Mw: 15,000 |
| (3) | 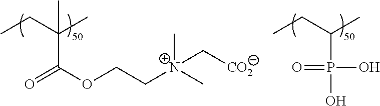 | Mw: 15,000 |
| (4) | 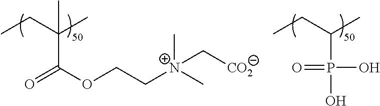 | Mw: 350,000 |
| (5) | 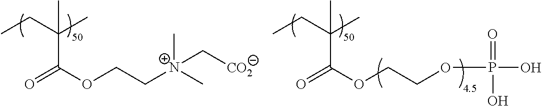 | Mw: 30,000 |
| (6) | 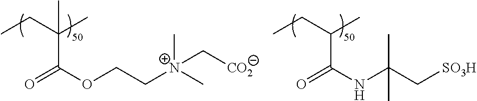 | Mw: 30,000 |
| (7) | 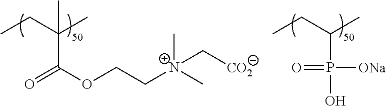 | Mw: 25,000 |
| (8) | 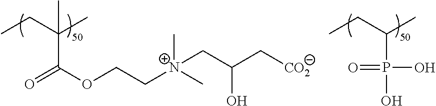 | Mw: 20,000 |
| (9) | 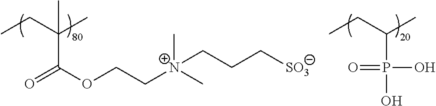 | Mw: 20,000 |
| (10) | 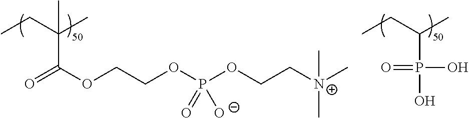 | Mw: 15,000 |
| (11) | 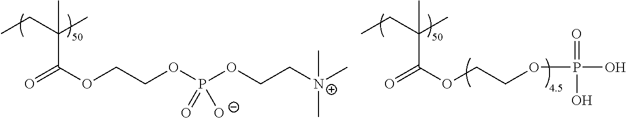 | Mw: 15,000 |
| (12) | 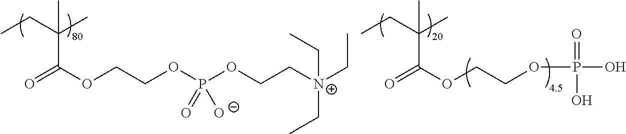 | Mw: 350,000 |
| (13) | 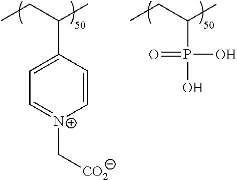 | Mw: 5,000 |
| (14) | 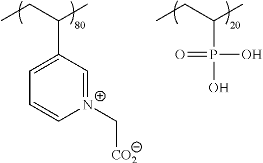 | Mw: 3,000 |
| (15) | 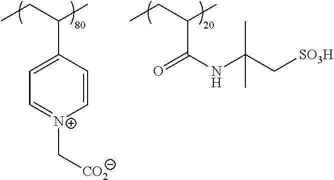 | Mw: 5,000 |
| (16) | 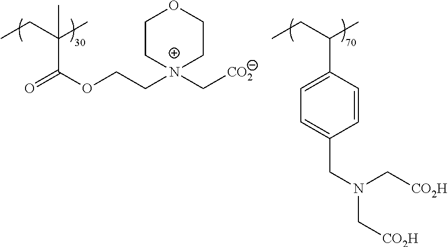 | Mw: 5,000 |
| (17) | 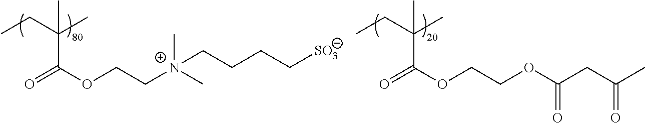 | Mw: 35,000 |
| (18) | 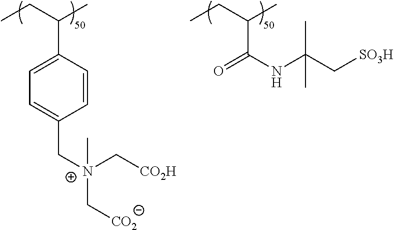 | Mw: 6,000 |
| (19) | 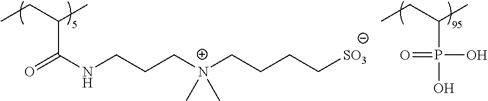 | Mw: 15,500 |
| (20) | 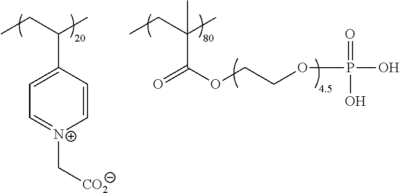 | Mw: 30,000 |
| (21) | 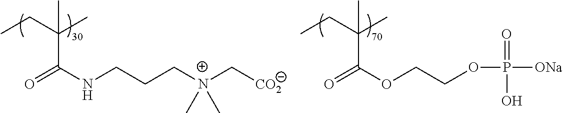 | Mw: 10,000 |
| (22) | 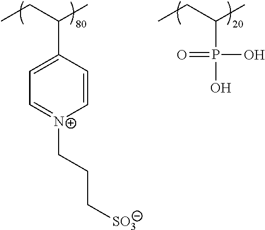 | Mw: 8,000 |
| (23) | 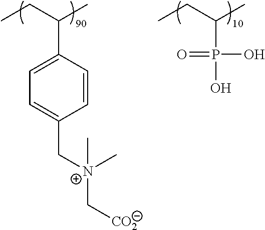 | Mw: 4,000 |
| (24) | 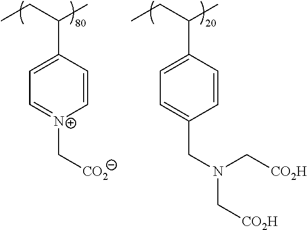 | Mw: 50,000 |
| (D1-1) | 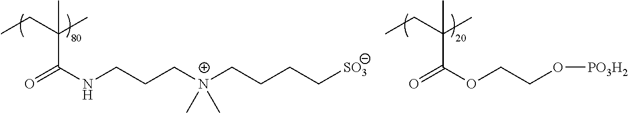 | MW: 20,000 |
| (D1-2) | 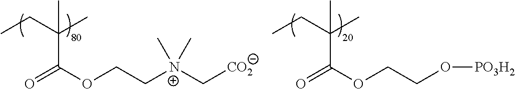 | MW: 20,000 |
| (D1-3) | 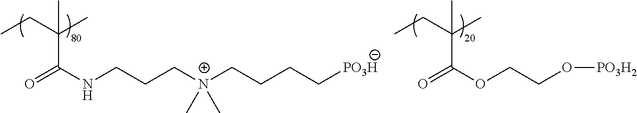 | MW: 20,000 |
| (D1-4) | 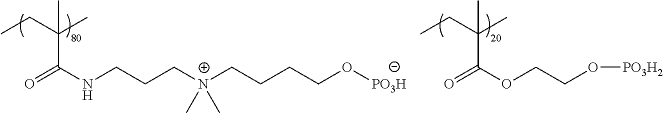 | MW: 20,000 |
| (D1-5) | 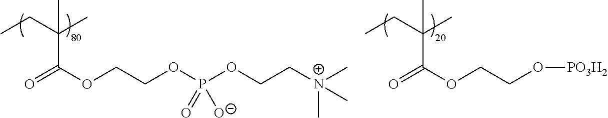 | MW: 20,000 |
| (D1-6) | 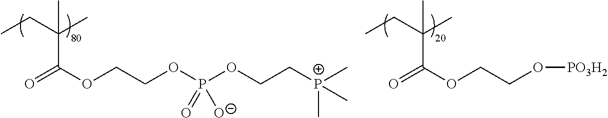 | MW: 20,000 |
| (D1-7) | 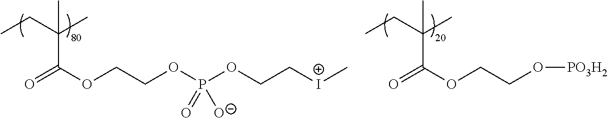 | MW: 20,000 |
| (D1-8) | 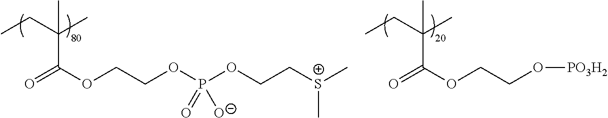 | MW: 20,000 |
| (D1-9) | 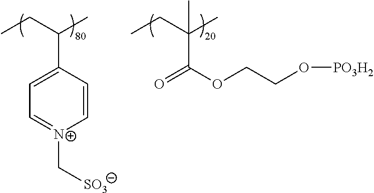 | MW: 20,000 |
| (D1-10) | 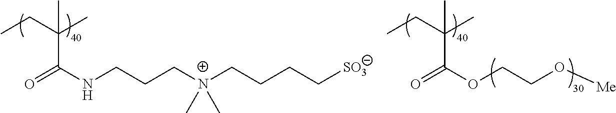 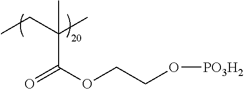 | MW: 20,000 |
| (D1-11) | 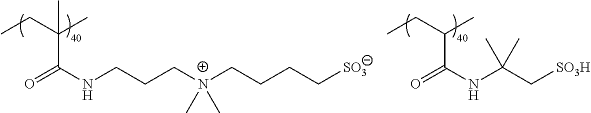 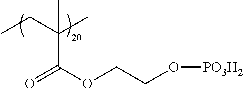 | MW: 20,000 |
| (D1-12) | 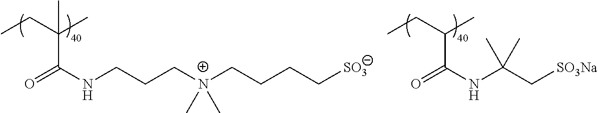 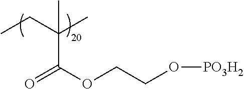 | MW: 20,000 |
| (D1-13) | 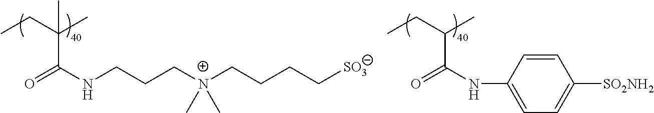 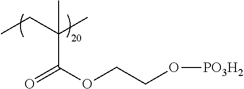 | MW: 20,000 |
| (D1-14) | 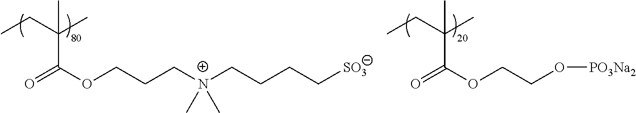 | MW: 20,000 |

The specific polymer compound (D2) which can be used in the lithographic printing plate precursor according to the invention is a copolymer containing (a3) a repeating unit having an ethylenically unsaturated bond and (a2) a repeating unit having a structure capable of interacting with a surface of the support.

The repeating unit (a3) having an ethylenically unsaturated bond contained in the specific polymer compound (D2) is not particularly restricted and a repeating unit having well-known structure represented by formula (B1) shown below as described, for example, in JP-A-2005-125749 can be used.

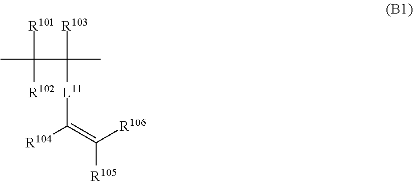

In formula (B1), R¹⁰¹ to R¹⁰³ each independently represents a hydrogen atom, an alkyl group having from 1 to 6 carbon atoms or a halogen atom. R¹⁰⁴ to R¹⁰⁶ each independently represents a hydrogen atom, an alkyl group having from 1 to 6 carbon atoms, a halogen atom, an acyl group or an acyloxy group, or R¹⁰⁴ and R¹⁰⁵ or R¹⁰⁵ and R¹⁰⁶ may form a ring. L¹¹ represents a divalent connecting group selected from the group consisting of —CO—, —O—, —NH—, a divalent aliphatic group, a divalent aromatic group and a combination thereof.

Specific examples of the combination of groups represented by L¹¹ are set forth below. In each of the specific examples shown below, the left side connects to the main chain and the right side connects to the ethylenically unsaturated bond.

L101: —CO—NH-divalent aliphatic group-O—CO—

L102: —CO-divalent aliphatic group-O—CO—

L103: —CO—O-divalent aliphatic group-O—CO—

L104: -divalent aliphatic group-O—CO—

L105: —CO—NH-divalent aromatic group-O—CO—

L106: —CO-divalent aromatic group-O—CO—

L107: -divalent aromatic group-O—CO—

L108: —CO—O-divalent aliphatic group-CO—O-divalent aliphatic group-O—CO—

L109: —CO—O-divalent aliphatic group-O—CO-divalent aliphatic group-O—CO—

L110: —CO—O-divalent aromatic group-CO—O-divalent aliphatic group-O—CO—

L111: —CO—O-divalent aromatic group-O—CO-divalent aliphatic group-O—CO—

L112: —CO—O-divalent aliphatic group-CO—O-divalent aromatic group-O—CO—

L113: —CO—O-divalent aliphatic group-O—CO-divalent aromatic group-O—CO—

L114: —CO—O-divalent aromatic group-CO—O-divalent aromatic group-O—CO—

L115: —CO—O-divalent aromatic group-O—CO-divalent aromatic group-O—CO—

L116: —CO—O-divalent aromatic group-O—CO—NH-divalent aliphatic group-O—CO—

L117: —CO—O-divalent aliphatic group-O—CO—NH-divalent aliphatic group-O—CO—

The divalent aliphatic group includes an alkylene group, a substituted alkylene group, an alkenylene group, a substituted alkenylene group, an alkinylene group, a substituted alkinylene group and a polyalkyleneoxy group. Among them, an alkylene group, a substituted alkylene group, an alkenylene group and a substituted alkenylene group are preferred, and an alkylene group and a substituted alkylene group are more preferred. Of the divalent aliphatic groups, a chain structure is preferred than a cyclic structure, and further a straight-chain structure is preferred than a branched structure.

A number of carbon atoms included in the divalent aliphatic group is preferably from 1 to 20, more preferably from 1 to 15, still more preferably from 1 to 12, yet still more preferably from 1 to 10, and most preferably from 1 to 8.

Examples of the substituent for the divalent aliphatic group include a halogen atom (e.g., F, Cl, Br or I), a hydroxy group, a carboxyl group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, an arylamino group and a diarylamino group.

The divalent aromatic group includes an arylene group and a substituted arylene group. It preferably includes a phenylene group, a substituted phenylene group, a naphthylene group and a substituted naphthylene group.

Examples of the substituent for the divalent aromatic group include an alkyl group in addition to the substituents described for the divalent aliphatic group described above.

Of L101 to L117 described above, L101, L103, L105, L107 and L117 are preferred.

As the repeating unit (a2) having a structure capable of interacting with a surface of the support contained in the specific polymer compound (D2), a repeating unit having the structure same as in the repeating unit (a2) contained in the specific polymer compound (D1) can be used. Among them, from the standpoint of stain resistance and printing durability, the functional group capable of interacting with a surface of the support in (a2) is preferably a carboxylic acid group or a salt thereof, a sulfonic acid group or a salt thereof, a phosphoric acid ester group or a salt thereof or a phosphonic acid group or a salt thereof. In view of further improvement in the stain resistance, a phosphoric acid ester group or a salt thereof or a phosphonic acid group or a salt thereof is more preferred.

The specific polymer compound (D2) may contain a repeating unit other than the repeating units (a2) and (a3) described above.

Specific examples of the specific polymer compound (D2) are set forth below, but the invention should not be construed as being limited thereto. The symbol x, y or z attached to the polymer structure indicates a molar percentage of the repeating unit.

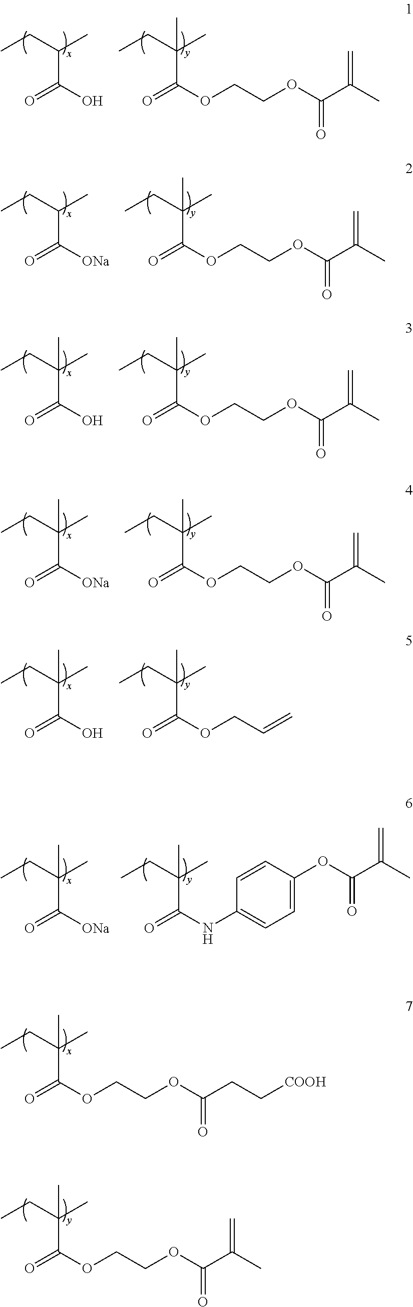

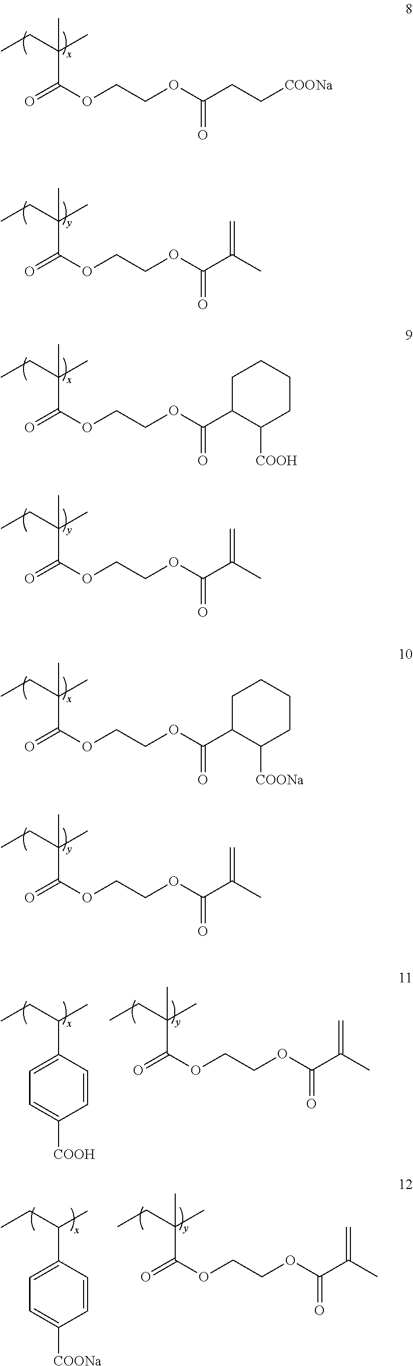

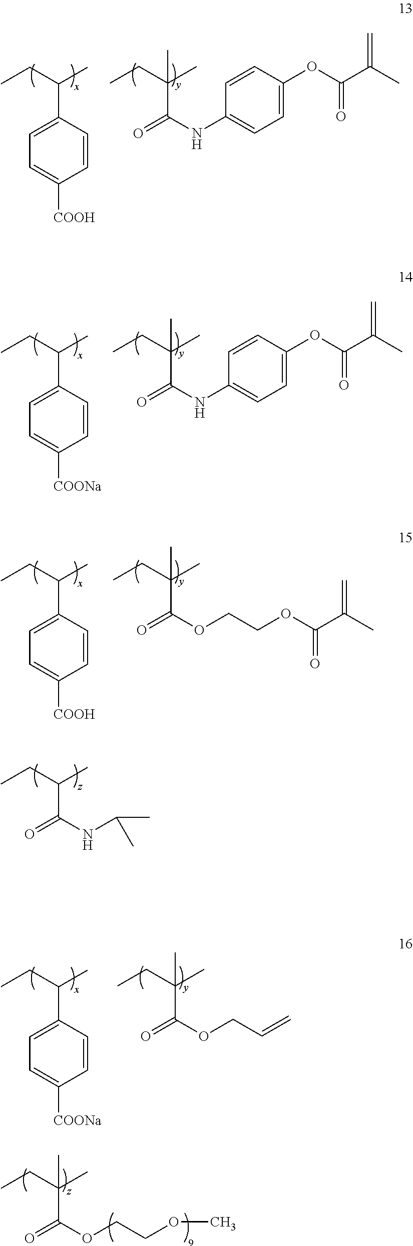

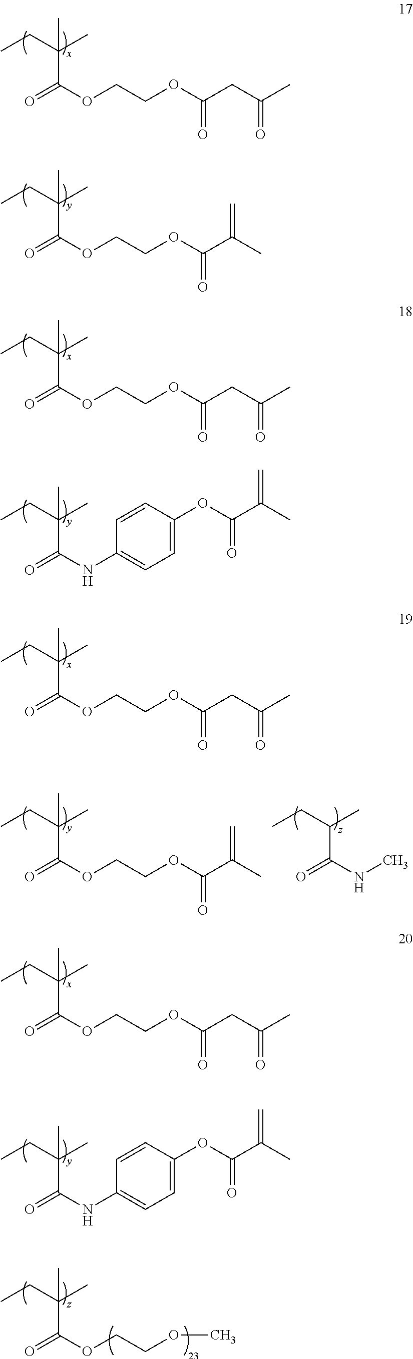

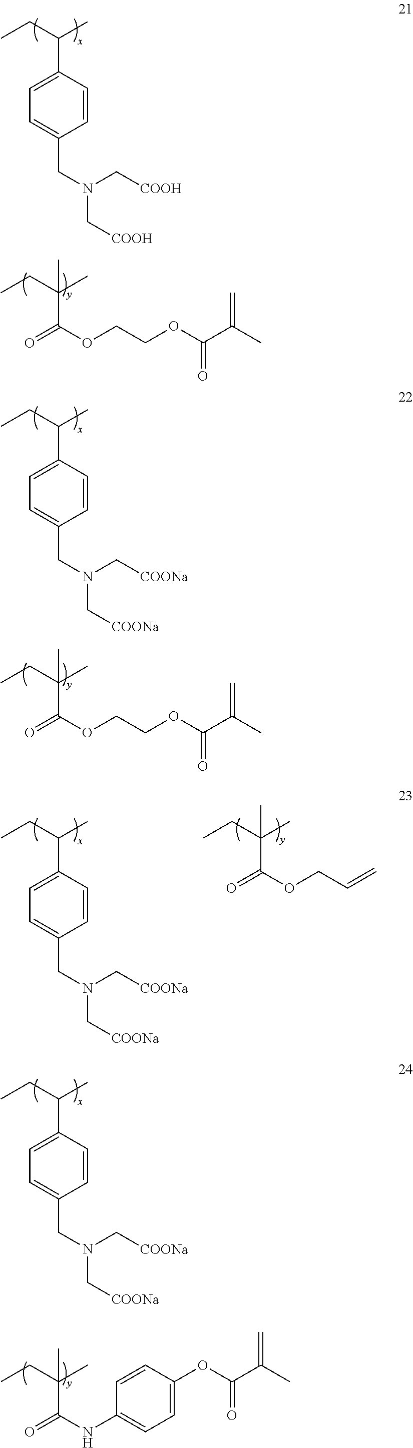

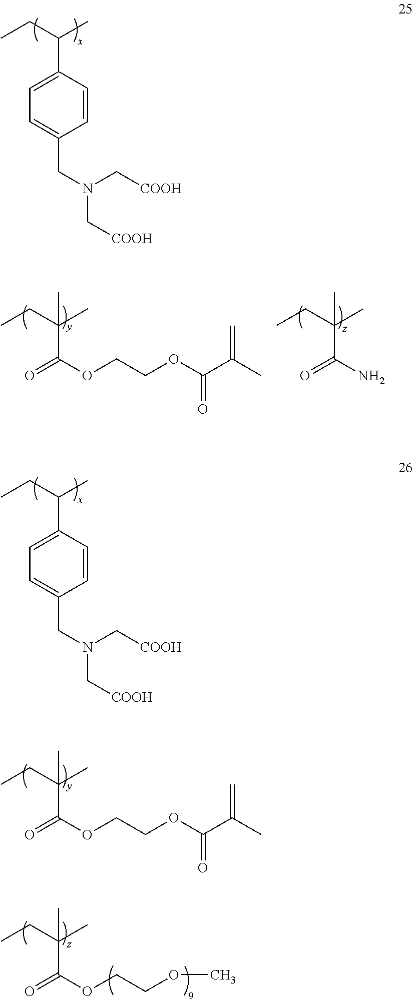

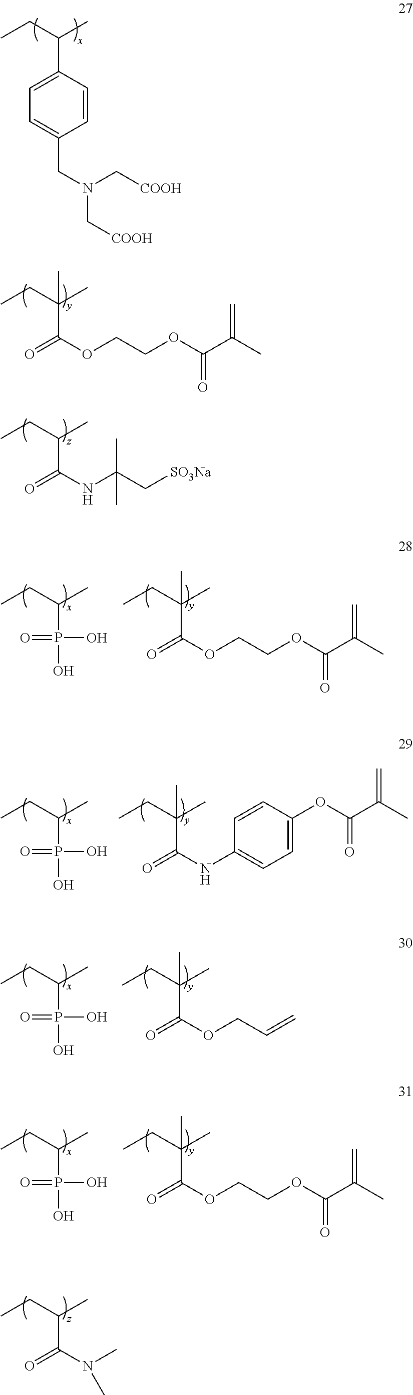

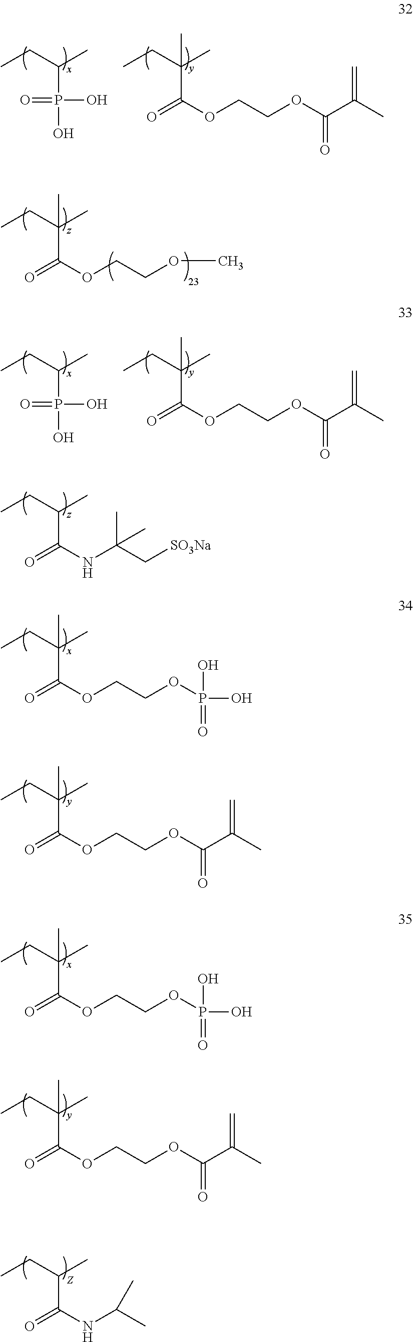

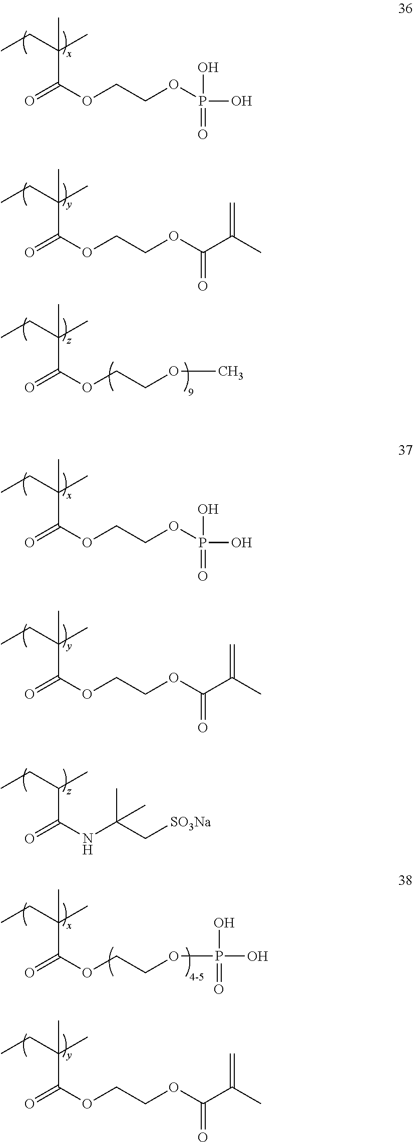

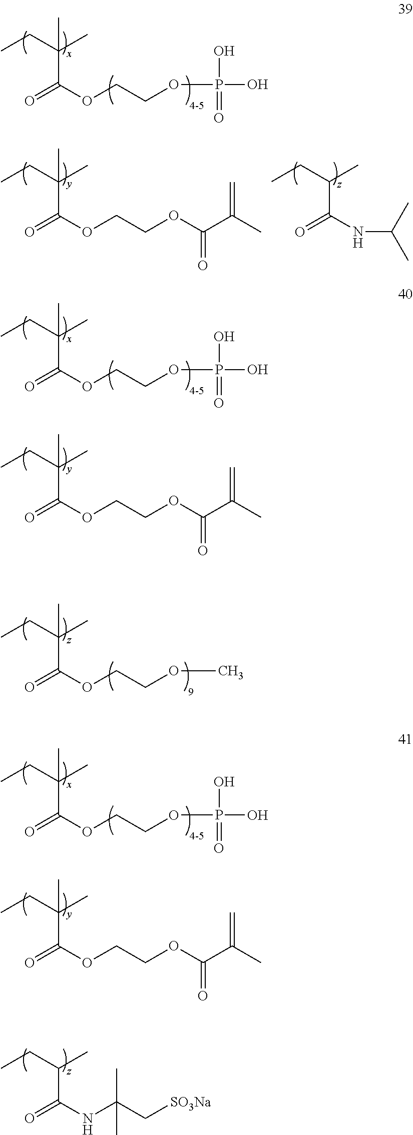

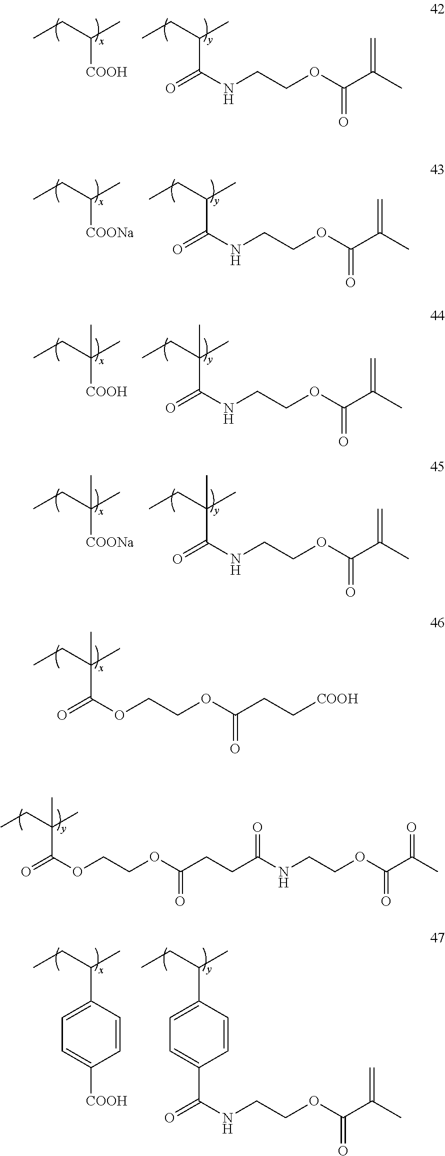

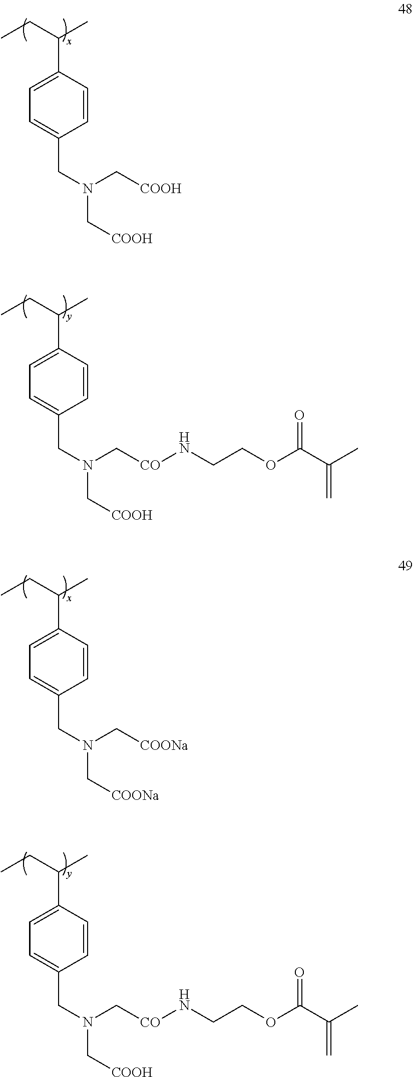

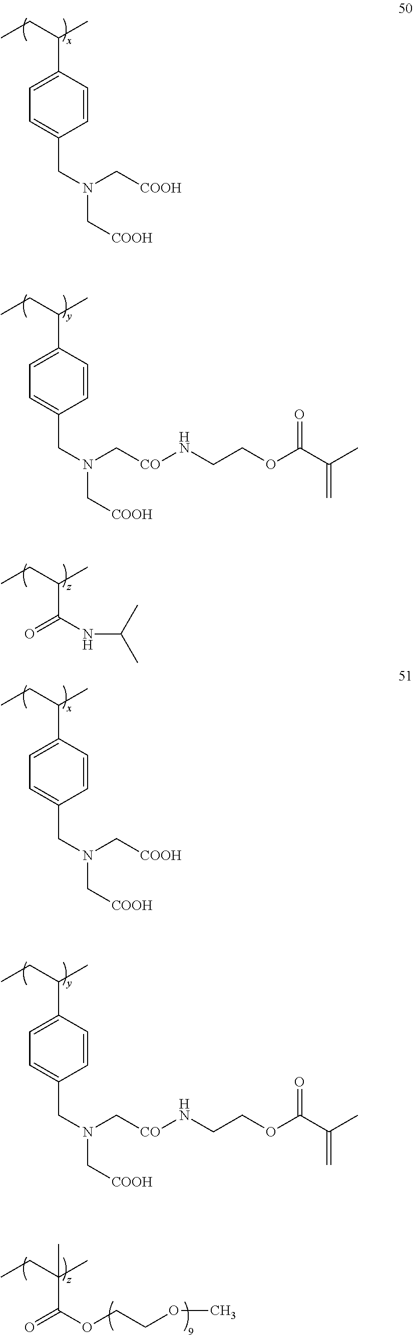

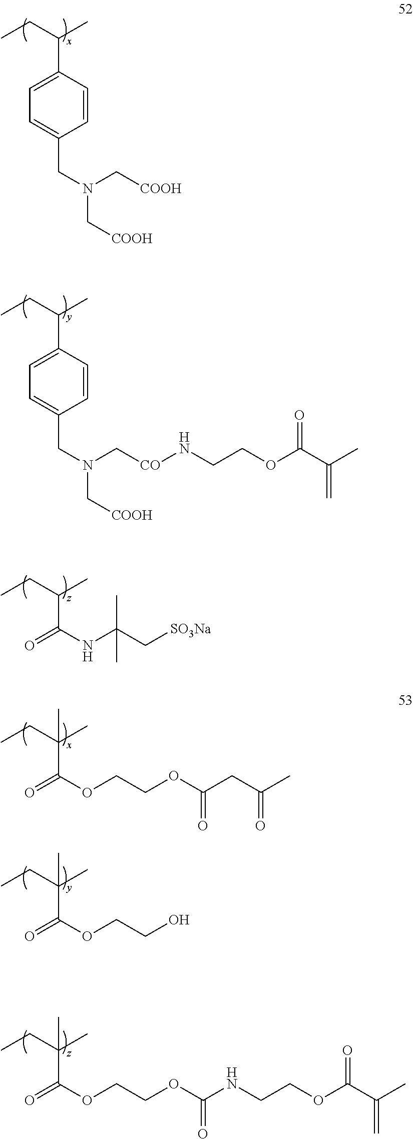

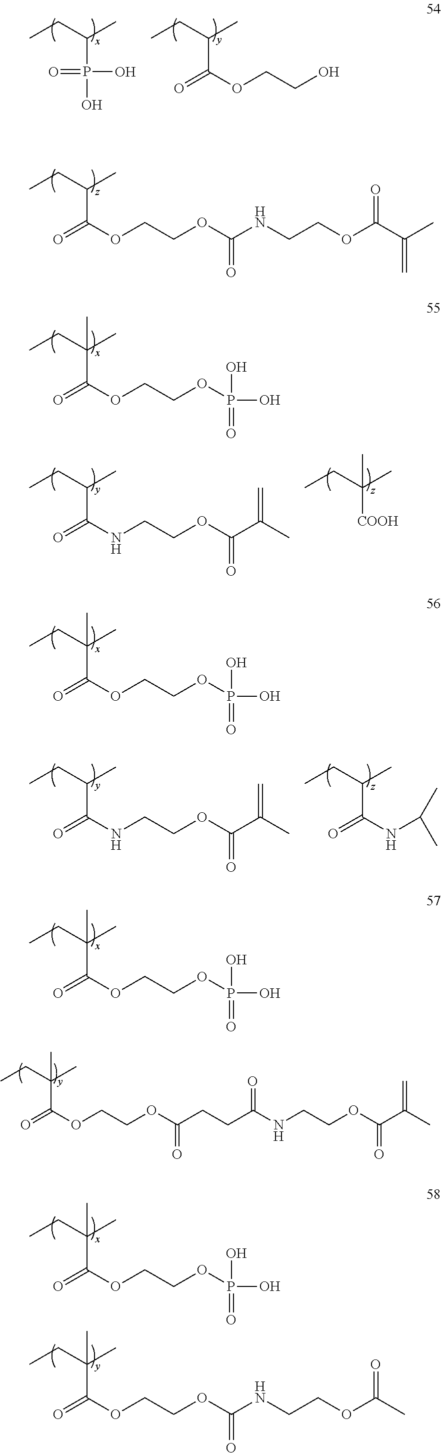

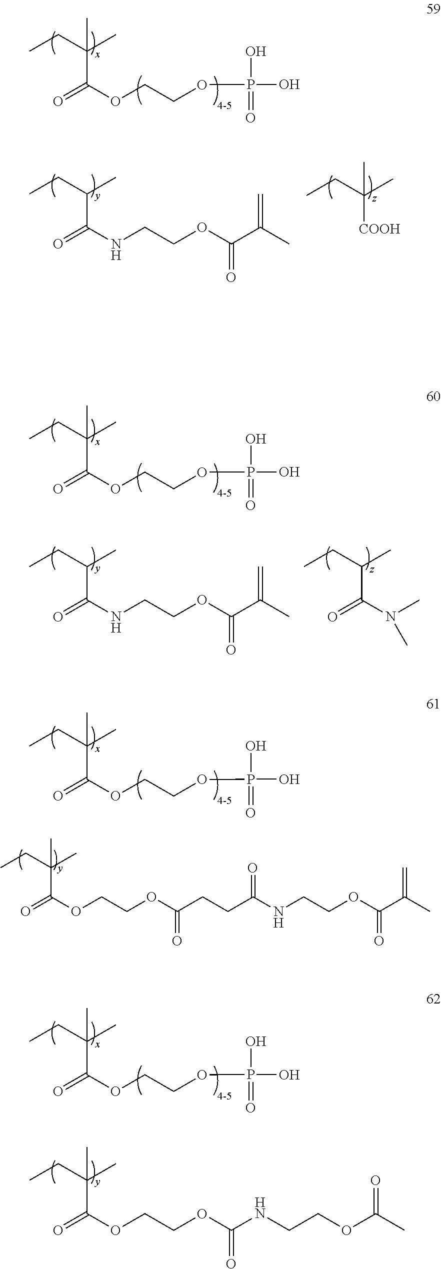

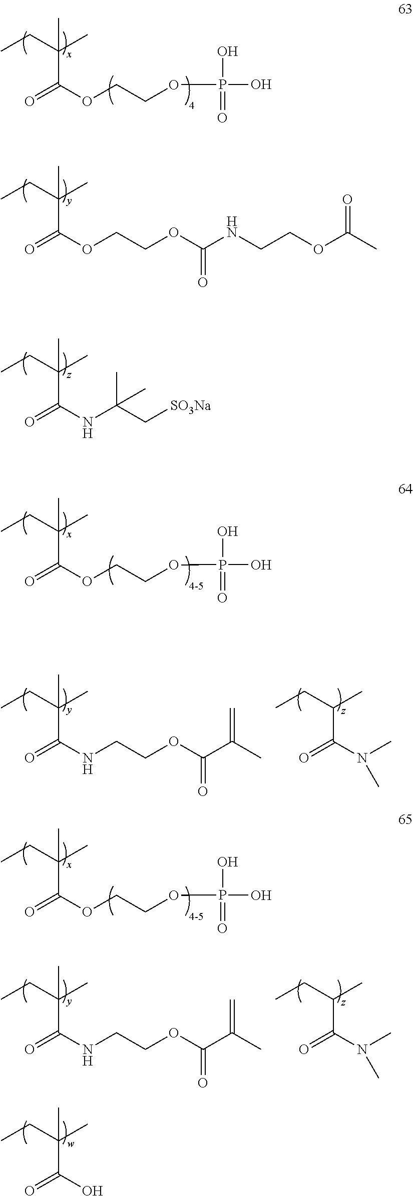

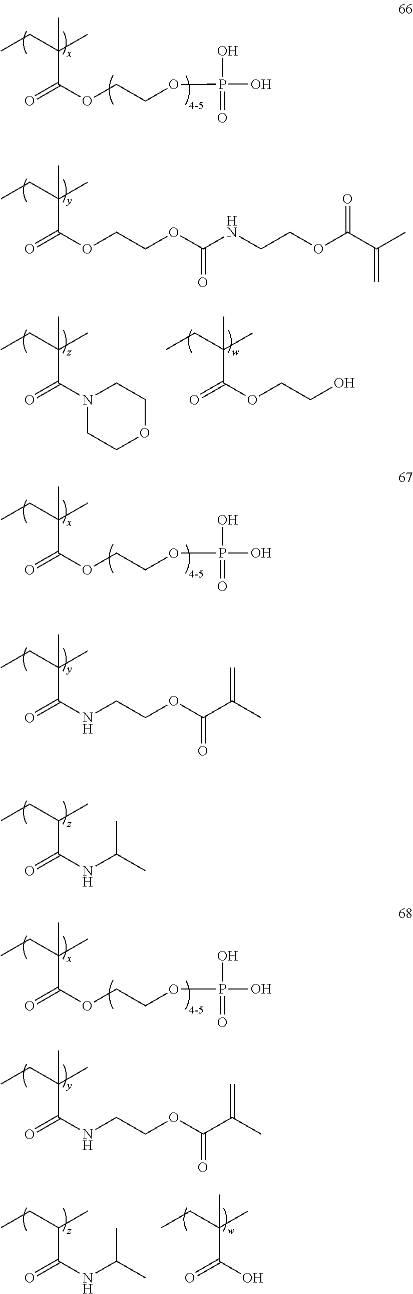

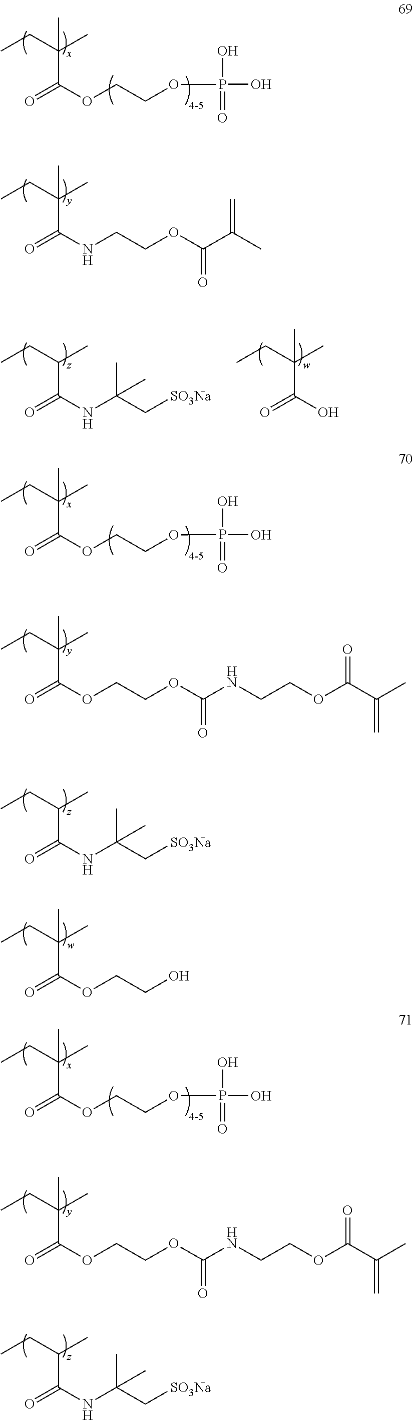

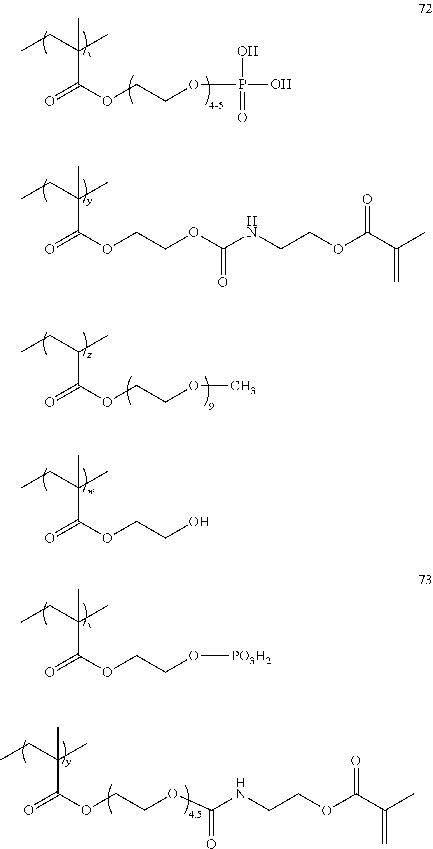

As to a suitable content range of the specific polymer compounds (D1) and (D2), a coating amount (solid content) of the specific polymer compounds (D1) and (D2) is preferably from 0.1 to 100 mg/m², more preferably from 3 to 50 mg/m², and still more preferably from 5 to 30 mg/m².

As to a suitable blend ratio of the specific polymer compounds (D1) and (D2), when a weight of the copolymer (D1) is from 5 to 95% based on a total weight of the copolymers (D1) and (D2), the printing durability and stain resistance at an acceptable level can be obtained. In order to improve the balance between the printing durability and stain resistance, the weight of the copolymer (D1) is preferably from 10 to 90%, and more preferably from 30 to 70%.

The undercoat layer containing the specific polymer compounds (D1) and (D2) can be provided, for example, by dissolving the specific polymer compounds (D1) and (D2) in a solvent to prepare a coating solution and coating the coating solution according to a known method.

As the solvent, water and an organic solvent, for example, methanol, ethanol, propanol, isopropanol, ethylene glycol, hexylene glycol, THF, DMF, 1-methyoxy-2-propanol, dimethylacetamide or dimethylsulfoxide are exemplified and an alcohol is particularly preferred. The organic solvents may be used as a mixture.

The undercoat layer which can be used in the lithographic printing plate precursor according to the invention may contain a known compound, for example, a chelating agent, a secondary or tertiary amine, a polymerization inhibitor or a compound containing an amino group or a functional group having polymerization inhibition ability and a group capable of interacting with a surface of aluminum support (for example, 1,4-diazabicyclo[2,2,2]octane (DABCO), 2,3,5,6-tetrahydroxy-p-quinone, chloranil, sulfophthalic acid, hydroxyethylethylenediaminetriacetic acid, dihydroxyethylethylenediaminediacetic acid or hydroxyethyliminodiacetic acid) in addition to the specific polymer compounds described above.

### [Image-Recording Layer]

### <(A) Polymerization Initiator>

The polymerization initiator which can be used in the image-recording layer of the lithographic printing plate precursor according to the invention indicates a compound which initiates or accelerates polymerization of a polymerizable compound. The polymerization initiator usable in the invention is preferably a radical polymerization initiator and includes, for example, known thermal polymerization initiators, compounds containing a bond having small bond dissociation energy and photopolymerization initiators.

The polymerization initiator according to the invention include, for example, (a) an organic halide, (b) a carbonyl compound, (c) an azo compound, (d) an organic peroxide, (e) a metallocene compound, (f) an azide compound, (g) a hexaarylbiimidazole compound, (h) an organic borate compound, (i) a disulfone compound, (j) an oxime ester compound and (k) an onium salt compound.

As the organic halide (a), compounds described in Paragraph Nos. [0022] to [0023] of JP-A-2008-195018 are preferred.

As the carbonyl compound (b), compounds described in Paragraph No. [0024] of JP-A-2008-195018 are preferred.

As the azo compound (c), for example, azo compounds described in JP-A-8-108621 can be used.

As the organic peroxide (d), for example, compounds described in Paragraph No. [0025] of JP-A-2008-195018 are preferred.

As the metallocene compound (e), for example, compounds described in Paragraph No. [0026] of JP-A-2008-195018 are preferred.

As the azide compound (f), a compound, for example, 2,6-bis(4-azidobenzylidene)-4-methylcyclohexanone is exemplified.

As the hexaarylbiimidazole compound (g), for example, compounds described in Paragraph No. [0027] of JP-A-2008-195018 are preferred.

As the organic borate compound (h), for example, compounds described in Paragraph No. [0028] of JP-A-2008-195018 are preferred.

As the disulfone compound (i), for example, compounds described in JP-A-61-166544 and JP-A-2002-328465 are exemplified.

As the oxime ester compound (j), for example, compounds described in Paragraph Nos. [0028] to [0030] of JP-A-2008-195018 are preferred.

As the onium salt compound (k), onium salts, for example, diazonium salts described in S. I. Schlesinger, Photogr. Sci. Eng., 18, 387 (1974), T. S. Bal et al., Polymer, 21, 423 (1980) and JP-A-5-158230, ammonium salts described in U.S. Pat. No. 4,069,055 and JP-A-4-365049, phosphonium salts described in U.S. Pat. Nos. 4,069,055 and 4,069,056, iodonium salts described in European Patent 104,143, U.S. Patent Publication No. 2008/0311520, JP-A-2-150848, JP-A-2008-195018 and J. V. Crivello et al., Macromolecules, 10 (6), 1307 (1977), sulfonium salts described in European Patents 370,693, 233,567, 297,443 and 297,442, U.S. Pat. Nos. 4,933,377, 4,760,013, 4,734,444 and 2,833,827 and German Patents 2,904,626, 3,604,580 and 3,604,581, selenonium salts described in J. V. Crivello et al., J. Polymer Sci., Polymer Chem. Ed., 17, 1047 (1979), arsonium salts described in C. S. Wen et al., Teh, Proc. Conf. Rad. Curing ASIA, p. 478, Tokyo, Oct. (1988), and azinium salts described in JP-A-2008-195018 are exemplified.

Of the polymerization initiators described above, the onium salt, in particular, the iodonium salt, the sulfonium salt or the azinium salt is more preferred. Specific examples of these compounds are set forth below, but the invention should not be construed as being limited thereto.

Of the iodonium salts, a diphenyliodonium salt is preferred. In particular, a diphenyliodonium salt substituted with an electron donating group, for example, an alkyl group or an alkoxy group is preferred, and an asymmetric diphenyliodonium salt is more preferred. Specific examples of the iodonium salt include diphenyliodonium hexafluorophosphate, 4-methoxyphenyl-4-(2-methylpropyl)phenyliodonium hexafluorophosphate, 4-(2-methylpropyl)phenyl-p-tolyliodonium hexafluorophosphate, 4-hexyloxyphenyl-2,4,6-trimethoxyphenyliodonium hexafluorophosphate, 4-hexyloxyphenyl-2,4-diethoxyphenyliodonium tetrafluoroborate, 4-octyloxyphenyl-2,4,6-trimethoxyphenyliodonium 1-perfluorobutanesulfonate, 4-octyloxyphenyl-2,4,6-trimethoxyphenyliodonium hexafluorophosphate and bis(4-tert-butylphenyl)iodonium tetraphenylborate.

Examples of the sulfonium salt include triphenylsulfonium hexafluorophosphate, triphenylsulfonium benzoylformate, bis(4-chlorophenyl)phenylsulfonium benzoylformate, bis(4-chlorophenyl)-4-methylphenylsulfonium tetrafluoroborate, tris(4-chlorophenyl)sulfonium 3,5-bis(methoxycarbonyl)benzenesulfonate and tris(4-chlorophenyl)sulfonium hexafluorophosphate.

Examples of the azinium salt include 1-cyclohexylmethyloxypyridinium hexafluorophosphate, 1-cyclohexyloxy-4-phenylpyridinium hexafluorophosphate, 1-ethoxy-4-phenylpyridinium hexafluorophosphate, 1-(2-ethylhexyloxy)-4-phenylpyridinium hexafluorophosphate, 4-chloro-1-cyclohexylmethyloxypyridinium hexafluorophosphate, 1-ethoxy-4-cyanopyridinium hexafluorophosphate, 3,4-dichloro-1-(2-ethylhexyloxy)pyridinium hexafluorophosphate, 1-benzyloxy-4-phenylpyridinium hexafluorophosphate, 1-phenethyloxy-4-phenylpyridinium hexafluorophosphate, 1-(2-ethylhexyloxy)-4-phenylpyridinium p-toluenesulfonate, 1-(2-ethylhexyloxy)-4-phenylpyridinium perfluorobutanesulfonate, 1-(2-ethylhexyloxy)-4-phenylpyridinium bromide and 1-(2-ethylhexyloxy)-4-phenylpyridinium tetrafluoroborate.

The polymerization initiator according to the invention can be added preferably in an amount from 0.1 to 50% by weight, more preferably from 0.5 to 30% by weight, particularly preferably from 0.8 to 20% by weight, based on the total solid content constituting the image-recording layer. In the range described above, good sensitivity and good stain resistance in the non-image area at the time of printing are obtained.

### <(B) Polymerizable Compound>

The polymerizable compound for use in the image-recording layer according to the invention is an addition-polymerizable compound having at least one ethylenically unsaturated double bond and it is selected from compounds having at least one, preferably two or more, terminal ethylenically unsaturated double bonds. The polymerizable compound has a chemical form, for example, a monomer, a prepolymer, specifically, a dimer, a trimer or an oligomer, or a mixture thereof. Examples of the monomer include an unsaturated carboxylic acid (for example, acrylic acid, methacrylic acid, itaconic acid, crotonic acid, isocrotonic acid or maleic acid) and an ester or amide thereof. Preferably, an ester of an unsaturated carboxylic acid with a polyhydric alcohol compound and an amide of an unsaturated carboxylic acid with a polyvalent amine compound are used. An addition reaction product of an unsaturated carboxylic acid ester or amide having a nucleophilic substituent, for example, a hydroxy group, an amino group or a mercapto group, with a monofunctional or polyfunctional isocyanate or epoxy compound, or a dehydration condensation reaction product of an unsaturated carboxylic acid ester or amide with a monofunctional or polyfunctional carboxylic acid is also preferably used. Moreover, an addition reaction product of an unsaturated carboxylic acid ester or amide having an electrophilic substituent, for example, an isocyanate group or an epoxy group with a monofunctional or polyfunctional alcohol, amine or thiol, or a substitution reaction product of an unsaturated carboxylic acid ester or amide having a releasable substituent, for example, a halogen group or a tosyloxy group with a monofunctional or polyfunctional alcohol, amine or thiol is also preferably used. In addition, compounds in which the unsaturated carboxylic acid described above is replaced by an unsaturated phosphonic acid, styrene, vinyl ether or the like can also be used. These compounds are described in references including JP-T-2006-508380, JP-A-2002-287344, JP-A-2008-256850, JP-A-2001-342222, JP-A-9-179296, JP-A-9-179297, JP-A-9-179298, JP-A-2004-294935, JP-A-2006-243493, JP-A-2002-275129, JP-A-2003-64130, JP-A-2003-280187 and JP-A-10-333321.

Specific examples of the monomer, which is an ester of a polyhydric alcohol compound with an unsaturated carboxylic acid, include, as an acrylic acid ester, for example, ethylene glycol diacrylate, 1,3-butanediol diacrylate, tetramethylene glycol diacrylate, propylene glycol diacrylate, trimethylolpropane triacrylate, hexanediol diacrylate, tetraethylene glycol diacrylate, pentaerythritol tetraacrylate, sorbitol triacrylate, isocyanuric acid ethylene oxide (EO) modified triacrylate and polyester acrylate oligomer. As a methacrylic acid ester, for example, tetramethylene glycol dimethacrylate, neopentyl glycol dimethacrylate, trimethylolpropane trimethacrylate, ethylene glycol dimethacrylate, pentaerythritol trimethacrylate, bis[p-(3-methacryloxy-2-hydroxypropoxy)phenyl]dimethylmethane and bis[p-(methacryloxyethoxy)phenyl]dimethylmethane are exemplified. Specific examples of the monomer, which is an amide of a polyvalent amine compound with an unsaturated carboxylic acid, include methylene bisacrylamide, methylene bismethacrylamide, 1,6-hexamethylene bisacrylamide, 1,6-hexamethylene bismethacrylamide, diethylenetriamine trisacrylamide, xylylene bisacrylamide and xylylene bismethacrylamide.

Urethane type addition-polymerizable compounds produced using an addition reaction between an isocyanate and a hydroxy group are also preferably used and specific examples thereof include vinylurethane compounds having two or more polymerizable vinyl groups per molecule obtained by adding a vinyl monomer containing a hydroxy group represented by formula (a) shown below to a polyisocyanate compound having two or more isocyanate groups per molecule, described in JP-B-48-41708.

CH₂═C(R⁴)COOCH₂CH(R⁵)OH (a)

wherein R⁴ and R⁵ each independently represents H or CH₃.

Also, urethane acrylates as described in JP-A-51-37193, JP-B-2-32293, JP-B-2-16765, JP-A-2003-344997 and JP-A-2006-65210, urethane compounds having an ethylene oxide skeleton described in JP-B-58-49860, JP-B-56-17654, JP-B-62-39417, JP-B-62-39418, JP-A-2000-250211 and JP-A-2007-94138, and urethane compounds having a hydrophilic group described in U.S. Pat. No. 7,153,632, JP-T-8-505958, JP-A-2007-293221 and JP-A-2007-293223 are preferably used.

Of the compounds described above, an isocyanuric acid ethyleneoxide-modified acrylate, for example, tris(acryloyloxyethyl) isocyanurate or bis(acryloyloxyethyl)hydroxyethyl isocyanurate is particularly preferred from the standpoint of excellent balance between hydrophilicity relating to the on-press development property and polymerization ability relating to the printing durability.

Details of the method of using the polymerizable compound, for example, selection of the structure, individual or combination use or an amount added, can be appropriately determined in accordance with the characteristic design of the final lithographic printing plate precursor. The polymerizable compound is used preferably in a range from 5 to 75% by weight, more preferably in a range from 10 to 70% by weight, particularly preferably in a range from 15 to 60% by weight, based on the total solid content of the image-recording layer.

### <(C) Binder Polymer>

The image-recording layer according to the invention contains a binder polymer. As the binder polymer, a polymer capable of holding the components of image-recording layer on a support and capable of being removed with dampening water and/or ink described hereinafter is used. The binder polymer used includes a (meth)acrylic polymer, a polyurethane resin, a polyvinyl alcohol resin, a polyvinyl butyral resin, a polyvinyl formal resin, a polyamide resin, a polyester resin and an epoxy resin. Particularly, a (meth)acrylic polymer, a vinyl copolymer, for example, a polyvinyl alcohol resin, a polyvinyl butyral resin or a polyvinyl formal resin and a polyurethane resin are preferably used.

As the binder polymer preferred for the invention, a polymer having a crosslinkable functional group for improving film strength of the image area in its main chain or side chain, preferably in its side chain, as described in JP-A-2008-195018 is exemplified.

In the binder polymer, a free radical (a polymerization initiating radical or a propagating radical in the process of polymerization of the polymerizable compound) is added to the crosslinkable functional group to cause an addition-polymerization between the polymers directly or through a polymerization chain of the polymerizable compound, as a result, crosslinkage is formed between the polymer molecules. Alternatively, an atom (for example, a hydrogen atom on the carbon atom adjacent to the functional crosslinkable group) in the polymer is withdrawn by a free radical to produce a polymer radical and the polymer radicals combine with each other to form crosslinkage between the polymer molecules. Due to the formation of crosslinkage, curing is accelerated.

As the crosslinkable functional group, an ethylenically unsaturated group, for example, a (meth)acryl group, a vinyl group, an allyl group or a styryl group or an epoxy group is preferred. The crosslinkable functional group can be introduced into the polymer by a polymer reaction or copolymerization. For instance, a reaction between an acrylic polymer or polyurethane having a carboxyl group in its side chain and glycidyl methacrylate or a reaction between a polymer having an epoxy group and a carboxylic acid containing an ethylenically unsaturated group, for example, methacrylic acid can be utilized.

Specific examples of the repeating unit having an ethylenically unsaturated group which may be contained in the binder polymer according to the invention are set forth below.

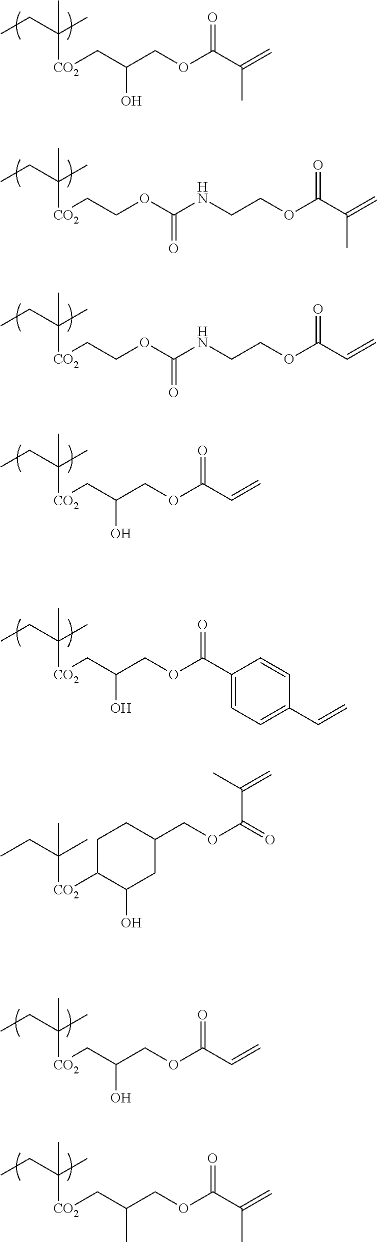

The content of the crosslinkable group in the binder polymer is preferably from 0.1 to 10.0 mmol, more preferably from 0.25 to 7.0 mmol, most preferably from 0.5 to 5.5 mmol, based on 1 g of the binder polymer.

It is also preferred that the binder polymer for use in the invention further contains a hydrophilic group. The hydrophilic group contributes to impart the on-press development property to the image-recording layer. In particular, coexistence of the crosslinkable group and the hydrophilic group makes it possible to maintain compatibility between the printing durability and development property.

The hydrophilic group includes, for example, a hydroxy group, a carboxyl group, an alkylene oxide structure, an amino group, an ammonium group, an amido group, a sulfo group and a phosphoric acid group. Among them, an alkylene oxide structure containing from 1 to 9 alkylene oxide units having 2 or 3 carbon atoms is preferred. In order to introduce a hydrophilic group into the binder polymer, a monomer having the hydrophilic group may be copolymerized.

In order to control the ink receptivity, an oleophilic group, for example, an alkyl group, an aryl group, an aralkyl group or an alkenyl group may be introduced into the binder polymer according to the invention. Specifically, an oleophilic group-containing monomer, for example, an alkyl methacrylate may be copolymerized.

Specific examples (1) to (11) of the binder polymer which can be used in the invention are set forth below, but the invention should not be construed as being limited thereto.

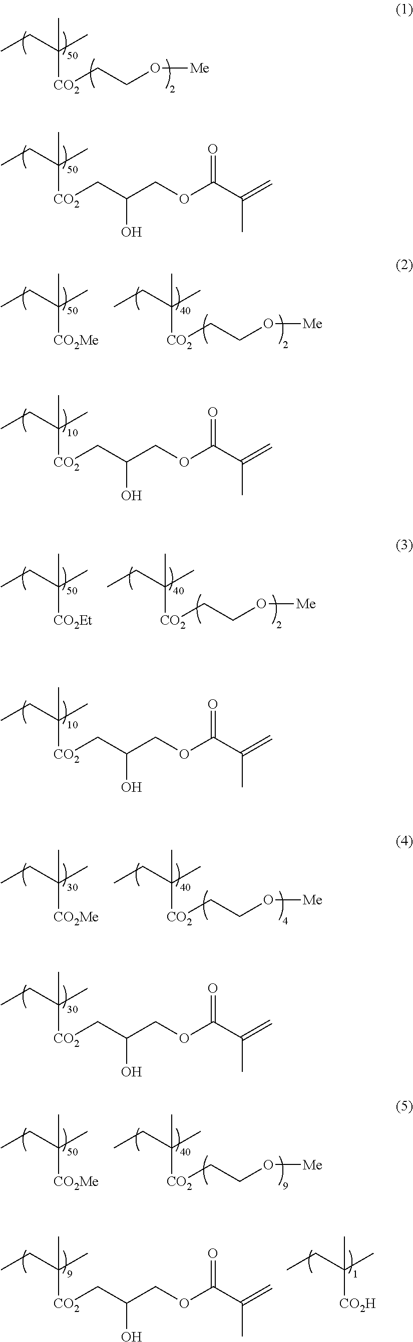

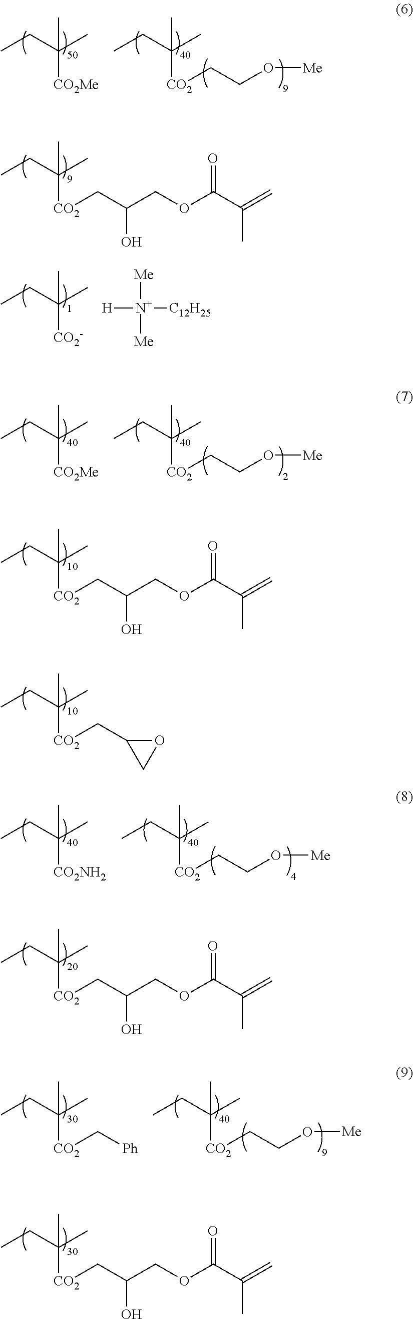

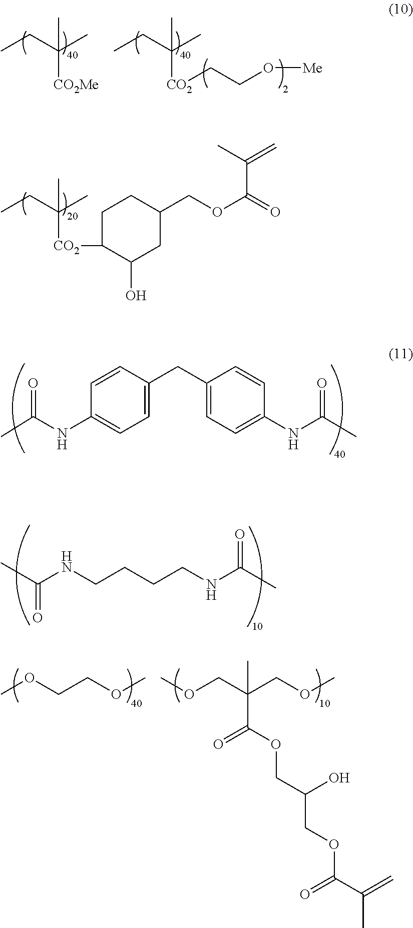

The weight average molecular weight (Mw) of the binder polymer according to the invention is preferably 2,000 or more, more preferably 5,000 or more, and still more preferably from 10,000 to 300,000. The number average molecular weight (Mn) thereof is preferably 1,000 or more, and more preferably from 2,000 to 250,000. The polydispersity (Mw/Mn) is preferably from 1.1 to 10.

The binder polymer which can be used in the invention may have a branched structure.

As the binder polymer having a branched structure, a polymer compound in which polymer chains are branched from an isocyanuric acid skeleton as a branch point represented by formula (1) shown below is particularly preferred.

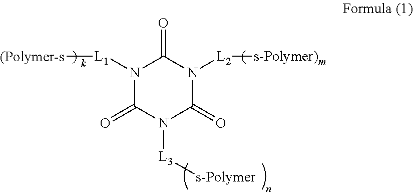

In formula (1), L₁ to L₃ each independently represents a divalent or higher valent connecting group containing one or more elements selected from C, O, N, halogen, P, Si, S and H, and is particularly preferably a divalent or higher valent connecting group containing one or more elements selected from C, O, N and H. m, n and k each independently represents an integer of 1 or more. Specific examples of L₁ to L₃ which can be used in the invention are set forth below, but the invention should not be construed as being limited thereto.

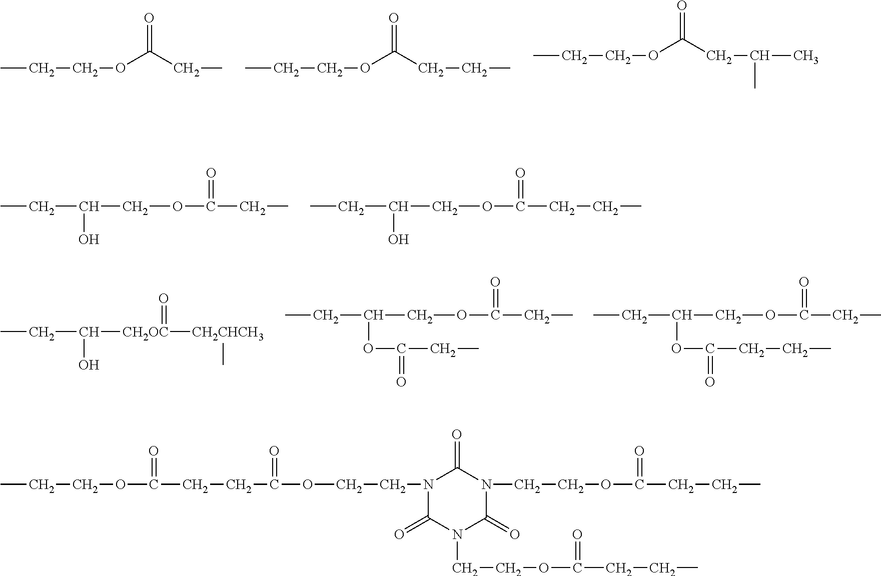

As Polymer in formula (1), any polymer chain may be preferably used as long as the structure in which polymer chains are branched from an isocyanuric acid skeleton as a branch point is maintained. For example, an acrylic resin and a polyvinyl acetal resin each having a film-forming property are exemplified.

Among them, the polymer chain is preferably formed by (b1) a repeating unit having at least one hydrophilic functional group and (b2) a repeating unit having at least one hydrophobic functional group.

The repeating unit having at least one hydrophilic functional group (b1) for forming the polymer chain includes repeating units having a functional group represented by —COOM¹, —SO₃M¹, —OH, —OSO₃M¹, —CONR¹R², —SO₂NR¹R², —NR¹SO₃M¹, —P(═O)(OM¹)(OM²), —OP(═O)(OM¹)(OM²), —Y³N⁺R¹R²L³¹A⁻, −Y³PO₄⁻L³²E⁺ (wherein M¹ and M² each represents a hydrogen ion, a metal ion, an ammonium ion or a phosphonium ion, and R¹ and R² each independently represents a hydrogen atom, an alkyl group, an alkenyl group, an aryl group or a heterocyclic group), ethylene oxide or propylene oxide.

R¹ and R² may be combined with each other to form a ring structure. L³¹ represents a connecting group. A⁻ represents a group containing an anion. Y³ represents a single bond or a divalent connecting group selected from the group consisting of —CO—, —O—, —NH—, a divalent aliphatic group, a divalent aromatic group and a combination thereof L³² represents a connecting group. E⁺ represents a group containing a cation.

In the case where any one of M¹ and M² represents the metal ion, specific examples of the metal ion include L⁺, Na⁺, K⁺ and Cu⁺. Of the metal ions, L⁺, Na⁺ or K⁺ is particularly preferred.

In the case where any one of M¹ and M² represents the ammonium ion, any ordinary ammonium ion can be preferably used and an ammonium ion having a number of carbon atoms of 24 or less per molecule is preferred and an ammonium ion having a number of carbon atoms of 16 or less per molecule is particularly preferred.

In the case where any one of M¹ and M² represents the phosphonium ion, any ordinary phosphonium ion can be preferably used and a phosphonium ion having a number of carbon atoms of 24 or less per molecule is preferred and a phosphonium ion having a number of carbon atoms of 16 or less per molecule is particularly preferred.

In the case where any one of R¹ and R² represents the alkyl group, any ordinary alkyl group can be used, and it may be a branched or cyclic form and may have a substituent, for example, a halogen atom, an ether group, a thioether group, a hydroxy group, a cyano group, a keto group, a carboxylic acid group, a carboxylate group, a carbonic acid ester group, a carbonic acid amido group, a sulfonic acid group, a sulfonate group, a sulfonic acid ester group, a sulfonamido group, a sulfone group, a sulfoxide group, a phenyl group, a phosphonic acid group, a phosphonate group, a phosphoric acid group, a phosphate group, an amino group, an aminocarbonyl group, an aminocarboxyl group or an aminosulfonyl group. As the alkyl group, an alkyl group having a total number of carbon atoms of 12 or less is particularly preferred.

In the case where any one of R¹ and R² represents the alkenyl group, any ordinary alkenyl group can be used, and it may be a branched or cyclic form and may have a substituent, for example, a halogen atom, an ether group, a thioether group, a hydroxy group, a cyano group, a keto group, a carboxylic acid group, a carboxylate group, a carbonic acid ester group, a carbonic acid amido group, a sulfonic acid group, a sulfonate group, a sulfonic acid ester group, a sulfonamido group, a sulfone group, a sulfoxide group, a phenyl group, a phosphonic acid group, a phosphonate group, a phosphoric acid group, a phosphate group, an amino group, an aminocarbonyl group, an aminocarboxyl group or an aminosulfonyl group. As the alkenyl group, an alkenyl group having a total number of carbon atoms of 12 or less is particularly preferred.

In the case where any one of R¹ and R² represents the aryl group, any ordinary aryl group can be preferably used. The aryl group may have a substituent, for example, a halogen atom, an ether group, a thioether group, a hydroxy group, a cyano group, a nitro group, a keto group, a carboxylic acid group, a carboxylate group, a carbonic acid ester group, a carbonic acid amido group, a sulfonic acid group, a sulfonate group, a sulfonic acid ester group, a sulfonamido group, a sulfone group, a sulfoxide group, a phenyl group, a phosphonic acid group, a phosphonate group, a phosphoric acid group, a phosphate group, an amino group, an aminocarbonyl group, an aminocarboxyl group or an aminosulfonyl group. As the aryl group, an aryl group having a total number of carbon atoms of 12 or less is particularly preferred.

As the repeating unit having at least one hydrophilic functional group (b1) for forming the polymer chain, any repeating unit is preferably used as long as it is formed from a repeating unit having at least one of the hydrophilic functional groups. Specific examples of the repeating unit having a hydrophilic functional group which can be used in the invention are set forth below, but the invention should not be construed as being limited thereto.

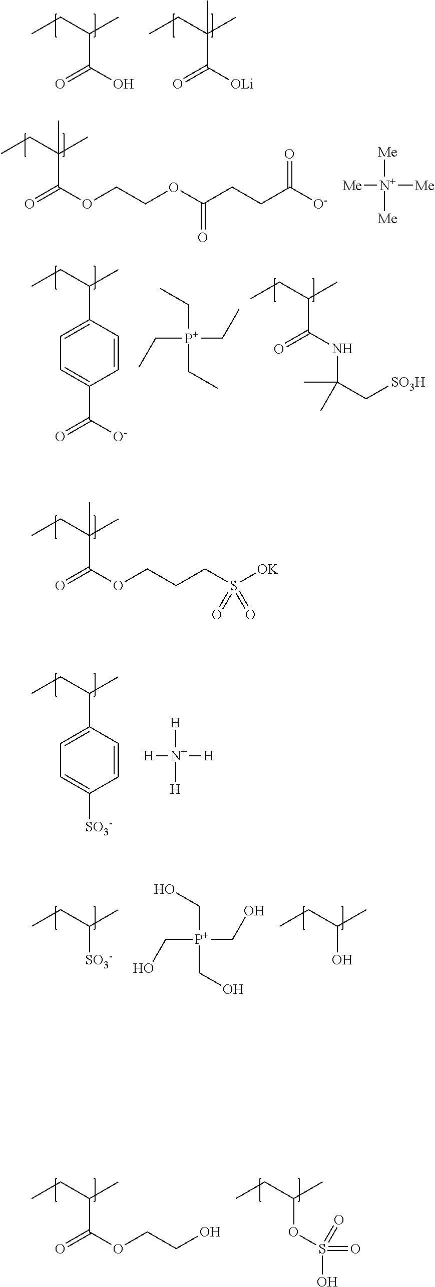

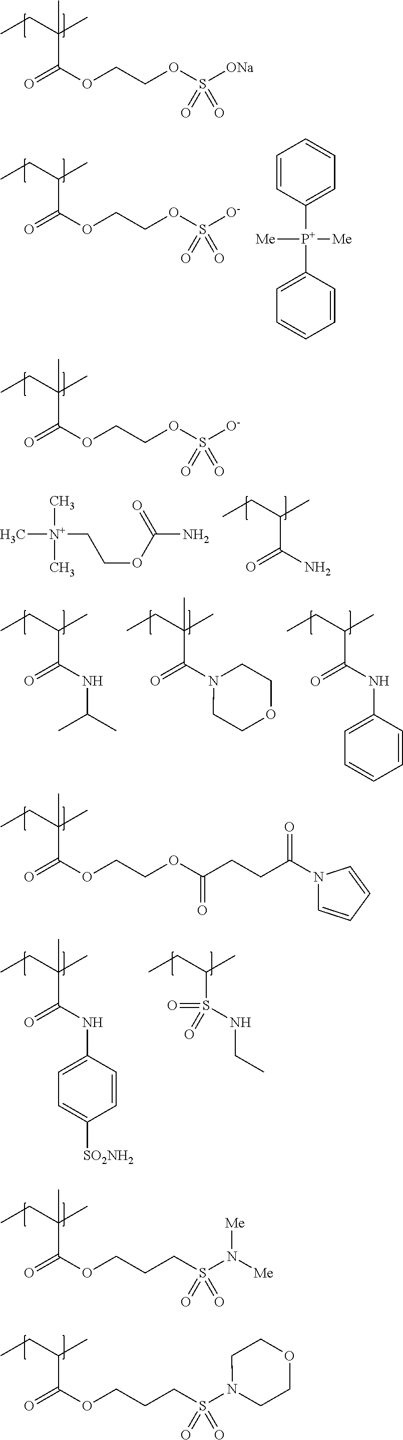

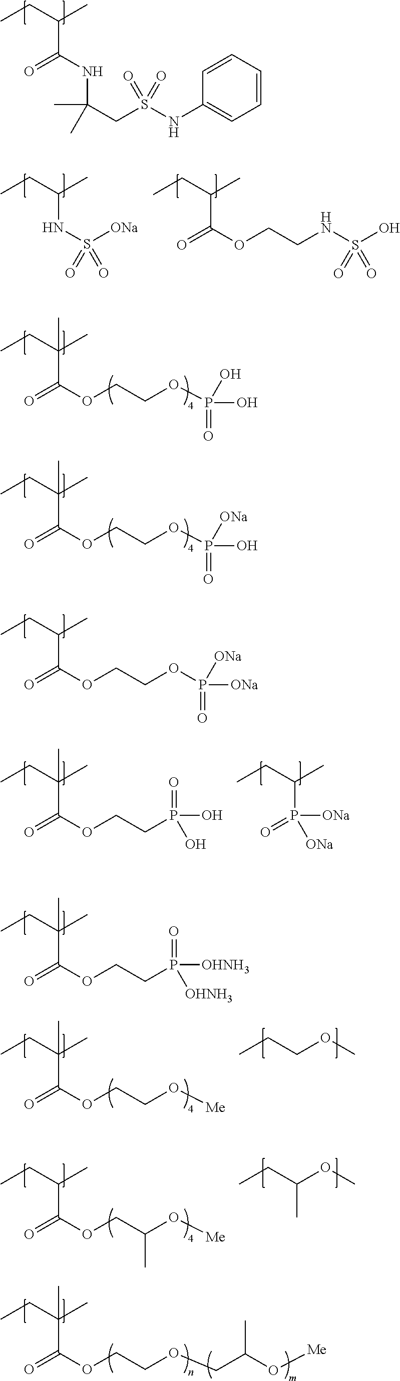

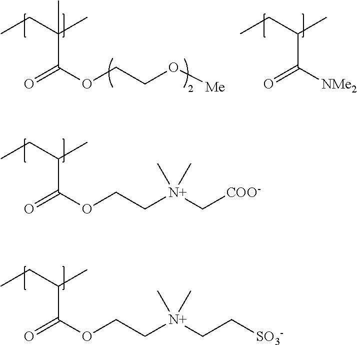

The repeating unit having at least one hydrophilic functional group (b1) for forming the polymer chain may be formed from only one kind or two or more kinds of the repeating units having the hydrophilic functional group as described above.

The repeating unit having at least one hydrophobic functional group (b2) for use in the polymer chain is a repeating unit which does not have the hydrophilic functional group described above. Specific examples of such a repeating unit are set forth below, but the invention should not be construed as being limited thereto.

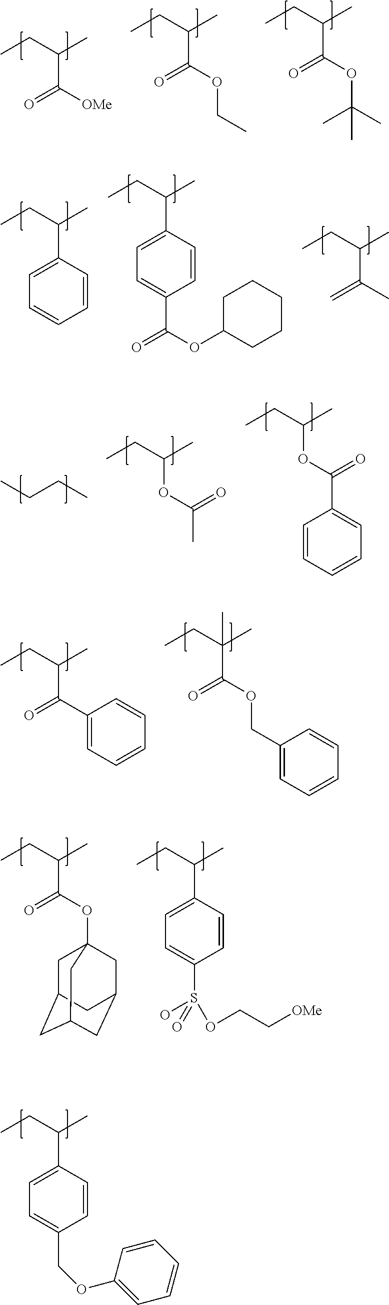

The repeating unit having at least one hydrophobic functional group (b2) for forming the polymer chain may be formed from only one kind or two or more kinds of the repeating units having the hydrophobic functional group as described above.

As Polymer in formula (1) for use in the invention, any polymer chain may be preferably used as long as it is formed from the repeating unit represented by formula (b1) and the repeating unit represented by formula (b2). The repeating unit (b1) is contained at a ratio preferably from 5 to 60% by mole, more preferably from 10 to 50% by mole, and the repeating unit (b2) is contained at a ratio preferably from 40 to 95% by mole, more preferably from 50 to 90% by mole.

In the binder polymer represented by formula (1), any polymer chain may be preferably used as long as the structure in which polymer chains are branched from an isocyanuric acid derivative as a branch point is maintained as described above and it is desired that the polymer chain branched contains a repeating unit having an ethylenically unsaturated group for the purpose of increasing film strength of the image area. Due to the ethylenically unsaturated group, crosslinkage is formed between the polymer molecules and curing is accelerated.

Specific examples of the ethylenically unsaturated group and the repeating unit having an ethylenically unsaturated group and the content of the ethylenically unsaturated group in the binder polymer are same as those described above with respect to the binder polymer having a not-branched structure.

Specific examples of the branched type binder polymer which can be used in the invention are set forth below, but the invention should not be construed as being limited thereto.

TABLE 1
Specific Examples of Branched Type Polymer According to Invention (1)

| Ex- | | | |
|---|---|---|---|
| am- | | | |
| ples | L1 | L2 | L3 |
| A-1 | 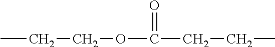 | 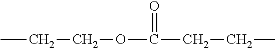 | 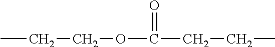 |
| A-2 | 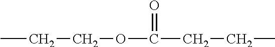 | 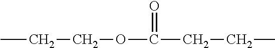 | 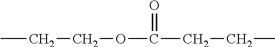 |
| A-3 | 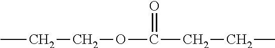 | 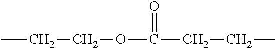 | 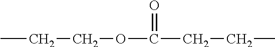 |
| A-4 | 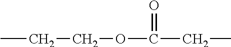 | 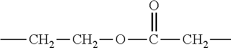 | 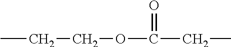 |
| A-5 | 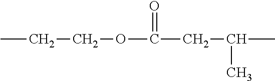 | 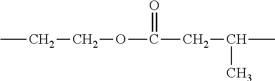 | 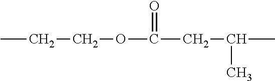 |
| A-6 | 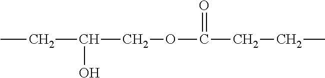 | 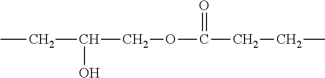 | 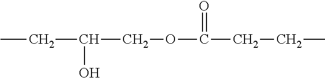 |
| A-7 | 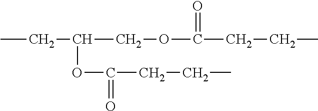 [SMILES: CCCC(=O)OCC(CC)OC(=O)CCC] | 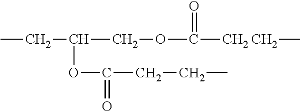 | 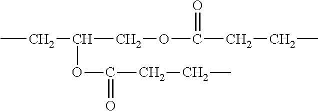 [SMILES: CCCC(=O)OCC(CC)OC(=O)CCC] |
| A-8 | 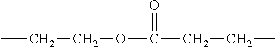 | 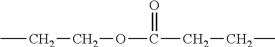 | 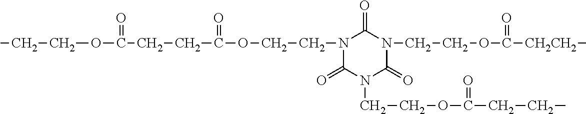 |
| A-9 | 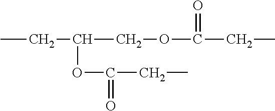 | 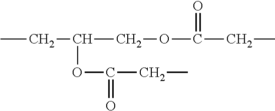 | 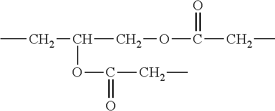 |
| A-10 | 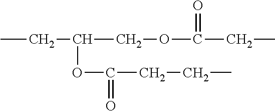 | 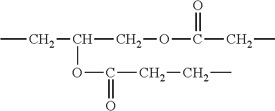 | 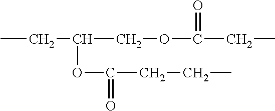 |

| Ex- | | | | | |
|---|---|---|---|---|---|
| am- | | | | | |
| ple | Polymer | n | m | k | Mw |
| A-1 | 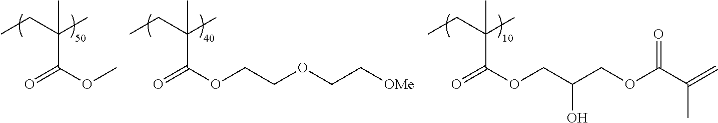 | 1 | 1 | 1 | 4.4 × 10⁴ |
| A-2 | 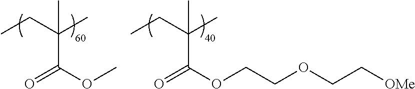 | 1 | 1 | 1 | 5.0 × 10⁴ |
| A-3 | 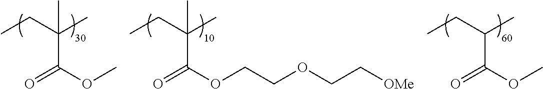 | 1 | 1 | 1 | 2.5 × 10⁴ |
| A-4 | 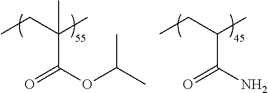 | 1 | 1 | 1 | 3.3 × 10⁴ |
| A-5 | 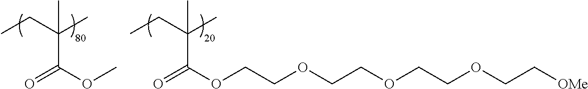 | 1 | 1 | 1 | 4.5 × 10⁴ |
| A-6 | 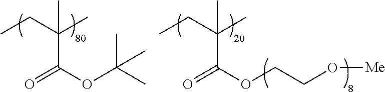 | 1 | 1 | 1 | 3.0 × 10⁴ |
| A-7 | 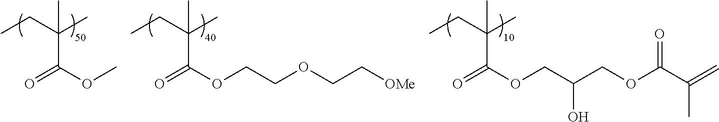 | 2 | 2 | 2 | 5.6 × 10⁴ |
| A-8 | 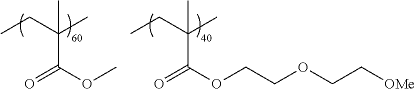 | 1 | 1 | 2 | 7.2 × 10⁴ |
| A-9 | 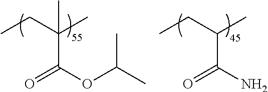 | 2 | 2 | 2 | 4.5 × 10⁴ |
| A-10 | 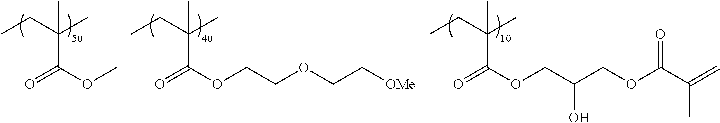 | 2 | 2 | 2 | 5.1 × 10⁴ |

TABLE 2
Specific Examples of Branched Type Polymer According to Invention (2)

| | | | |
|---|---|---|---|
| A-11 | 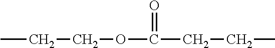 | 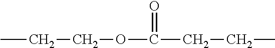 | 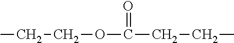 |
| A-12 | 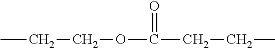 | 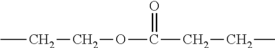 | 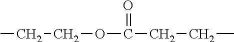 |
| A-13 | 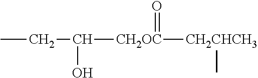 | 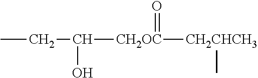 | 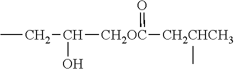 |
| A-14 | 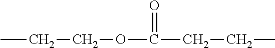 | 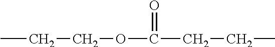 | 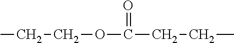 |
| A-15 | 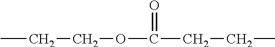 | 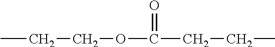 | 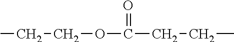 |
| A-16 | 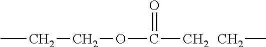 | 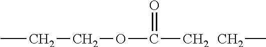 | 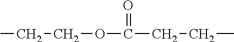 |
| A-17 | 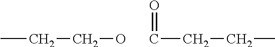 | 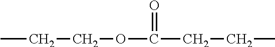 | 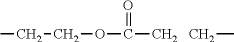 |
| A-18 | 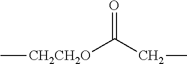 | 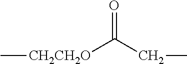 | 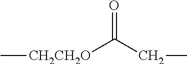 |
| A-19 | 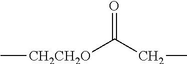 | 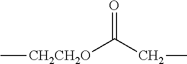 | 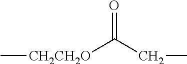 |
| A-20 | 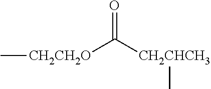 | 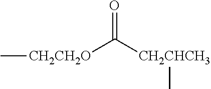 | 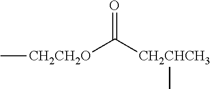 |

| | | | | | |
|---|---|---|---|---|---|
| A-11 | 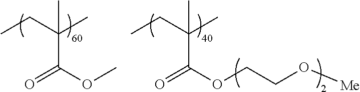 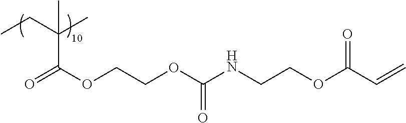 | 1 | 1 | 1 | 2.2 × 10⁴ |
| A-12 | 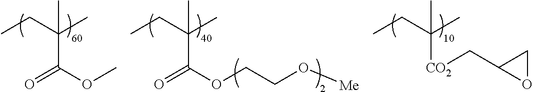 | 1 | 1 | 1 | 1.8 × 10⁴ |
| A-13 | 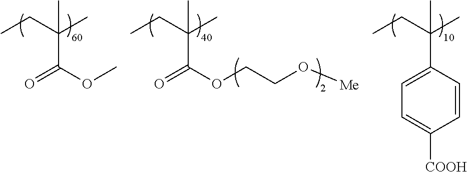 | 1 | 1 | 1 | 1.8 × 10⁴ |
| A-14 | 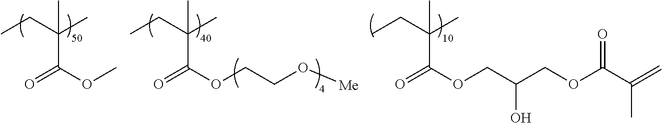 | 1 | 1 | 1 | 5.5 × 10⁴ |
| A-15 | 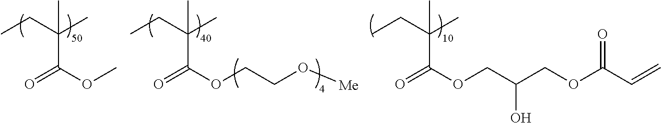 | 1 | 1 | 1 | 4.8 × 10⁴ |
| A-16 | 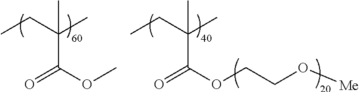 | 1 | 1 | 1 | 9.0 × 10⁴ |
| A-17 | 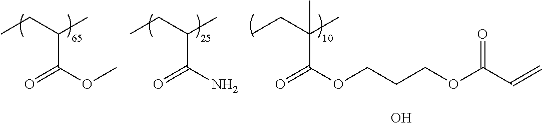 | 1 | 1 | 1 | 4.3 × 10⁴ |
| A-18 | 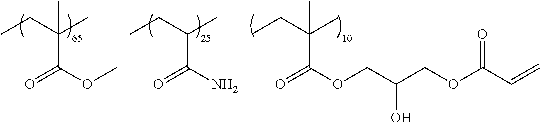 | 1 | 1 | 1 | 4.1 × 10⁴ |
| A-19 | 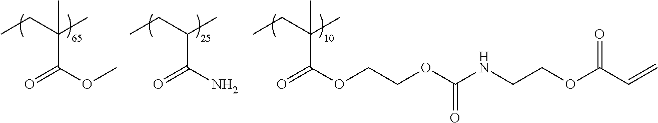 | 2 | 2 | 2 | 3.9 × 10⁴ |
| A-20 | 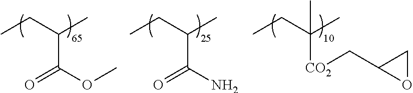 | 1 | 1 | 1 | 5.5 × 10⁴ |

TABLE 3
Specific Examples of Branched Type Polymer According to Invention (3)

| | | | |
|---|---|---|---|
| A-21 | 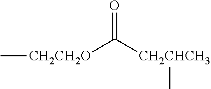 | 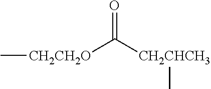 | 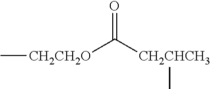 |
| A-22 | 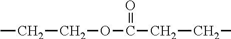 | 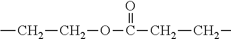 | 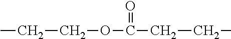 |
| A-23 | 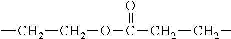 | 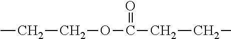 | 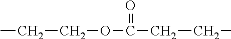 |
| A-24 | 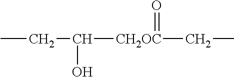 | 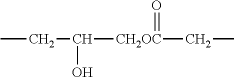 | 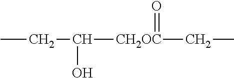 |
| A-25 | 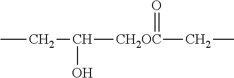 | 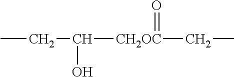 | 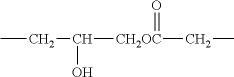 |
| A-26 | 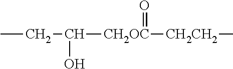 | 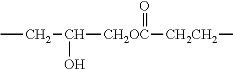 | 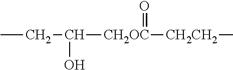 |
| A-27 | 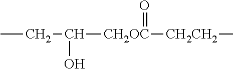 | 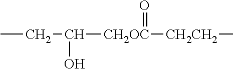 | 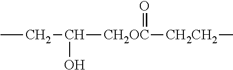 |
| A-28 | 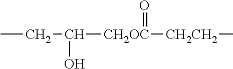 | 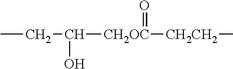 | 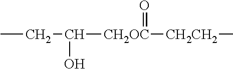 |
| A-29 | 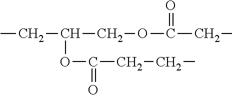 | 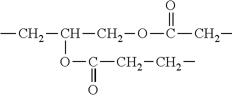 | 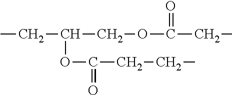 |
| A-30 | 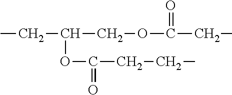 | 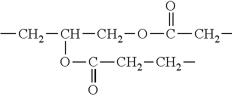 | 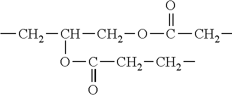 |
| A-31 | 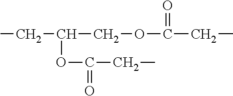 | 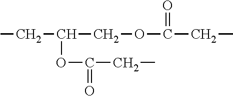 | 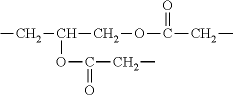 |
| A-32 | 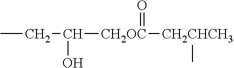 | 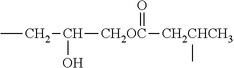 | 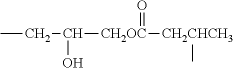 |
| A-33 | 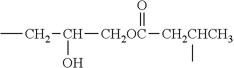 | 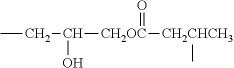 | 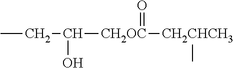 |

| | | | | | |
|---|---|---|---|---|---|
| A-21 | 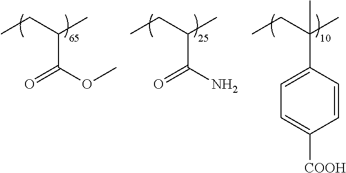 | 1 | 1 | 1 | 2.6 × 10⁴ |
| A-22 | 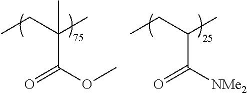 | 1 | 1 | 1 | 2.6 × 10⁴ |
| A-23 | 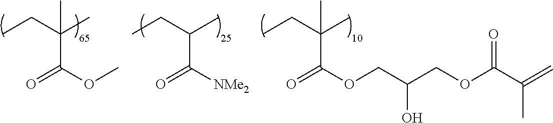 | 1 | 1 | 1 | 3.1 × 10⁴ |
| A-24 | 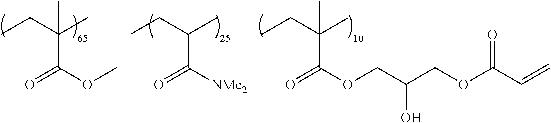 | 1 | 1 | 1 | 3.5 × 10⁴ |
| A-25 | 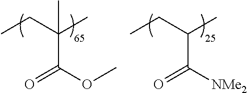 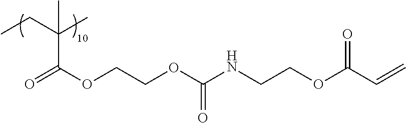 | 1 | 2 | 1 | 4.0 × 10⁴ |
| A-26 | 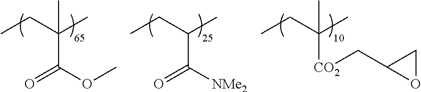 | 2 | 1 | 1 | 5.6 × 10⁴ |
| A-27 | 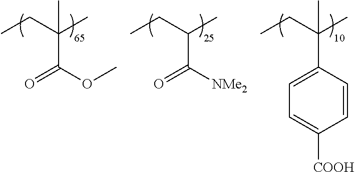 | 2 | 2 | 2 | 1.5 × 10⁴ |
| A-28 | 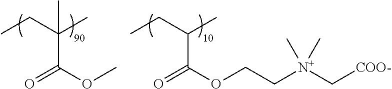 | 1 | 2 | 2 | 3.3 × 10⁴ |
| A-29 | 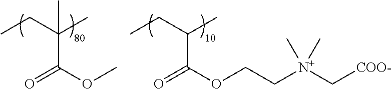 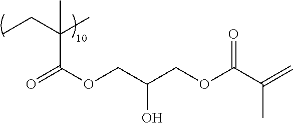 | 1 | 1 | 1 | 3.4 × 10⁴ |
| A-30 | 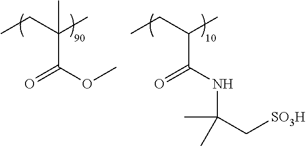 | 1 | 1 | 1 | 2.5 × 10⁴ |
| A-31 | 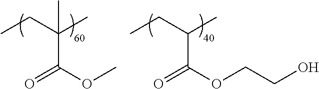 | 1 | 1 | 1 | 7.8 × 10⁴ |
| A-32 | 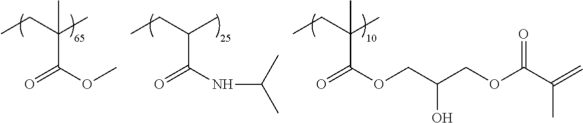 | 1 | 1 | 1 | 4.1 × 10⁴ |
| A-33 | 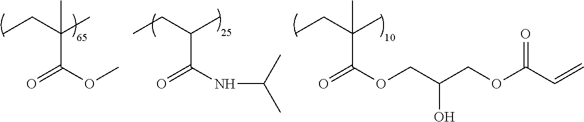 | 1 | 1 | 1 | 5.0 × 10⁴ |

The multi-branched type polymer described above can be synthesized by a known polymerization method, for example, a method comprising radical polymerization using a polymerization initiator and/or chain transfer agent containing a specific functional group in its molecule and then condensation of the resulting polymer with a polyfunctional compound having many functional groups capable of reacting with the specific functional group or a method of radical polymerization using a polyfunctional chain transfer agent, and the method of radical polymerization using a polyfunctional chain transfer agent is particularly preferred from the standpoint of ease of synthesis.

A weight average molecular weight (Mw) of the branched binder polymer described above is preferably from 5,000 to 500,000, and more preferably from 10,000 to 250,000.

The weight average molecular weight (Mw) is determined by a gel permeation chromatography (GPC) method using tetrahydrofuran as a developing solvent and mono-dispersed polystyrene as a standard substance.

According to the invention, a hydrophilic polymer, for example, polyacrylic acid or polyvinyl alcohol described in JP-A-2008-195018 may be used, if desired. Further, an oleophilic binder polymer may be used together with a hydrophilic binder polymer.

The binder polymer may be used individually or as a mixture of two or more thereof.

The content of the binder polymer in the image-recording layer is preferably from 0.5 to 90% by weight, more preferably from 1 to 80% by weight, still more preferably from 1.5 to 70% by weight, based on the total solid content of the image-recording layer.

### <Sensitizing Dye>

The image-recording layer preferably contains a sensitizing dye. The sensitizing dye can be used without particular restriction as far as it absorbs light at the image exposure to form the excited state and provides energy to a polymerization initiator with electron transfer, energy transfer or heat generation thereby improving the polymerization initiation function. Particularly, a sensitizing dye having an absorption maximum in a wavelength range from 350 to 450 nm or from 750 to 1,400 nm is preferably used.

Examples of the sensitizing dye having an absorption maximum in a wavelength range from 350 to 450 nm include a merocyanine dye, a benzopyran, a coumarin, an aromatic ketone and an anthracene.

Of the sensitizing dyes having an absorption maximum in a wavelength range from 350 to 450 nm, a dye represented by formula (IX) shown below is more preferred in view of high sensitivity.

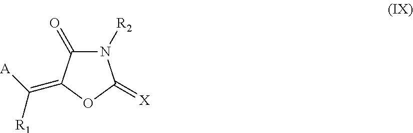

In formula (IX), A represents an aromatic cyclic group which may have a substituent or a heterocyclic group which may have a substituent, X represents an oxygen atom, a sulfur atom or N—(R₃), and R₁, R₂ and R₃ each independently represents a monovalent non-metallic atomic group, or A and R₁ or R₂ and R₃ may be combined with each other to form an aliphatic or aromatic ring.

R₁, R₂ and R₃ each independently represents a monovalent non-metallic atomic group, preferably a substituted or unsubstituted alkyl group, a substituted or unsubstituted alkenyl group, a substituted or unsubstituted aryl group, a substituted or unsubstituted aromatic heterocyclic residue, a substituted or unsubstituted alkoxy group, a substituted or unsubstituted alkylthio group, a hydroxy group or a halogen atom. A in formula (IX) represents an aromatic cyclic group which may have a substituent or a heterocyclic group which may have a substituent.

Specific examples of the sensitizing dye include compounds described in Paragraph Nos. [0047] to [0053] of JP-A-2007-58170.

Further, sensitizing dyes described in JP-A-2007-171406, JP-A-2007-206216, JP-A-2007-206217, JP-A-2007-225701, JP-A-2007-225702, JP-A-2007-316582 and JP-A-2007-328243 are also preferably used.

Next, the sensitizing dye having an absorption maximum in a wavelength range from 750 to 1,400 (hereinafter, referred to as an “infrared absorbing agent” in some cases) preferably used in the invention is described in detail below. The infrared absorbing agent used is preferably a dye or pigment.

As the dye, commercially available dyes and known dyes described in literatures, for example, Senryo Binran compiled by The Society of Synthetic Organic Chemistry, Japan (1970) can be used. Specifically, the dye includes an azo dye, a metal complex azo dye, a pyrazolone azo dye, a naphthoquinone dye, an anthraquinone dye, a phthalocyanine dye, a carbonium dye, a quinoneimine dye, a methine dye, a cyanine dye, a squarylium dye, a pyrylium salt and a metal thiolate complex.

Of the dyes, a cyanine dye, a squarylium dye, a pyrylium dye, a nickel thiolate complex and an indolenine cyanine dye are particularly preferred. Further, a cyanine dye and an indolenine cyanine dye are more preferred. As a particularly preferred example of the dye, a cyanine dye represented by formula (b) shown below is exemplified.

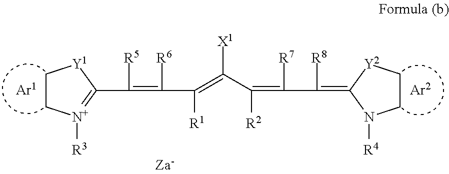

In formula (b), X¹ represents a hydrogen atom, a halogen atom, —NPh₂, X²-L¹ or a group shown below. X² represents an oxygen atom, a nitrogen atom or a sulfur atom, L¹ represents a hydrocarbon group having from 1 to 12 carbon atoms, an aromatic cyclic group containing a hetero atom (a nitrogen atom, a sulfur atom, an oxygen atom, a halogen atom or a selenium atom) or a hydrocarbon group having from 1 to 12 carbon atoms and containing a hetero atom. Xa⁻ has the same meaning as Za⁻ defined hereinafter. R^{a} represents a hydrogen atom or a substituent selected from an alkyl group, an aryl group, a substituted or unsubstituted amino group and a halogen atom.

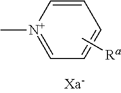

R¹ and R² each independently represents a hydrocarbon group having from 1 to 12 carbon atoms. In view of the preservation stability of a coating solution for image-recording layer, it is preferred that R¹ and R² each represents a hydrocarbon group having two or more carbon atoms, and it is particularly preferred that R¹ and R² are combined with each other to form a 5-membered or 6-membered ring.

Ar¹ and Ar², which may be the same or different, each represents an aromatic hydrocarbon group which may have a substituent. Preferable examples of the aromatic hydrocarbon group include a benzene ring group and a naphthalene ring group. Preferred examples of the substituent include a hydrocarbon group having 12 or less carbon atoms, a halogen atom and an alkoxy group having 12 or less carbon atoms. Y¹ and Y², which may be the same or different, each represents a sulfur atom or a dialkylmethylene group having 12 or less carbon atoms. R³ and R⁴, which may be the same or different, each represents a hydrocarbon group having 20 or less carbon atoms, which may have a substituent. Preferred examples of the substituent include an alkoxy group having 12 or less carbon atoms, a carboxyl group and a sulfo group. R⁵, R⁶, R⁷ and R⁸, which may be the same or different, each represents a hydrogen atom or a hydrocarbon group having 12 or less carbon atoms. In view of the availability of raw materials, a hydrogen atom is preferred. Za⁻ represents a counter anion. However, Za⁻ is not necessary when the cyanine dye represented by formula (b) has an anionic substituent in the structure thereof and neutralization of charge is not needed. Preferred examples of the counter ion for Za⁻ include a halide ion, a perchlorate ion, a tetrafluoroborate ion, a hexafluorophosphate ion and a sulfonate ion, and particularly preferred examples thereof include a perchlorate ion, a hexafluorophosphate ion and an arylsulfonate ion in view of the preservation stability of a coating solution for image-recording layer.

Specific examples of the cyanine dye represented by formula (b), which can be preferably used, include those described in Paragraph Nos. [0017] to [0019] of JP-A-2001-133969.

Further, other particularly preferred examples include specific indolenine cyanine dyes described in JP-A-2002-278057.

Examples of the pigment for use in the invention include commercially available pigments and pigments described in Colour Index (C.I.), Saishin Ganryo Binran compiled by Pigment Technology Society of Japan (1977), Saishin Ganryo Oyou Gijutsu, CMC Publishing Co., Ltd. (1986) and Insatsu Ink Gijutsu, CMC Publishing Co., Ltd. (1984).

The amount of the sensitizing dye added is preferably from 0.05 to 30 parts by weight, more preferably from 0.1 to 20 parts by weight, most preferably from 0.2 to 10 parts by weight, per 100 parts by weight of the total solid content of the image-recording layer.

### <Other Components of Image-Recording Layer>

The image-recording layer preferably further contains a chain transfer agent. As the chain transfer agent, for example, compounds having SH, PH, SiH or GeH in their molecules are used. The compound donates hydrogen to a low active radical species to generate a radical or is oxidized and deprotonized to generate a radical.

In particular, a thiol compound (for example, a 2-mercaptobenzimidazole, a 2-mercaptobenzothiazole, a 2-mercaptobenzoxazole, a 3-mercaptotriazole or a 5-mercaptotetrazole) is preferably used as the chain transfer agent in the image-recording layer.

Into the image-recording layer, a microcapsule or polymer fine particle described in Paragraph Nos. [0136] to [0141] of JP-A-2008-195018 can be incorporated in order to achieve good compatibility between the development property and the printing durability.

Into the image-recording layer, a hydrophilic low molecular weight compound (for example, tris(2-hydroxyethyl) isocyanurate or sodium 13-ethyl-5,8,11-trioxaheptadecane-1-sulfonate) described in Paragraph Nos. [0222] to [0231] of JP-A-2009-29124 can be incorporated in order to increase the development property.

Into the image-recording layer, an oil-sensitizing agent, for example, a phosphonium compound, a nitrogen-containing low molecular weight compound or an ammonium group-containing polymer can be used in order to increase the ink receptivity. In particular, in the case where an inorganic stratiform compound is incorporated into a protective layer described hereinafter, the oil-sensitizing agent functions as a surface covering agent of the inorganic stratiform compound and prevents deterioration of the ink receptivity during printing due to the inorganic stratiform compound.

As preferred examples of the phosphonium compound, phosphonium compounds (for example, 1,9-bis(triphenylphosphonio)nonane naphthalene-2,7-disulfonate) described in JP-A-2006-297907 and JP-A-2007-50660 are exemplified.

As the nitrogen-containing low molecular weight compound, compounds (for example, benzyldimethyldodecylammonium PF₆ salt) described in Paragraph Nos. [0021] to [0037] of JP-A-2008-284858 and Paragraph Nos. [0030] to [0057] of JP-A-2009-90645 are exemplified.

As the ammonium group-containing polymer, any polymer containing an ammonium group in its structure may be used and a polymer containing from 5 to 80% by mole of (meth)acrylate having an ammonium group in its side chain as a copolymerization component is preferably used. Specific examples thereof include polymers described in Paragraph Nos. [0089] to [0105] of JP-A-2009-208458.

As to the ammonium group-containing polymer, reduced viscosity value (unit: cSt/ml/g) determined according to the measuring method described in JP-A-2009-208458 is preferably in a range from 5 to 120, more preferably in a range from 10 to 110, and particularly preferably in a range from 15 to 100.

Into the image-recording layer, various additives can be further incorporated, if desired. Examples of the additive include a surfactant for progressing the development property and improving the surface state of coated layer, a coloring agent or print-out agent for visually distinguishing the image area from the non-image area, a polymerization inhibitor for preventing undesirable thermal polymerization of the radical polymerizable compound during the production and preservation of the image-recording layer, a higher fatty acid derivative for avoiding polymerization inhibition due to oxygen, an inorganic fine particle for increasing the cured film strength in the image area, and a plasticizer for improving plasticity. As the additives, known compounds are used and, for example, compounds described in Paragraph Nos. [0161] to [0215] of JP-A-2007-206217 can be used.

It is preferred that an unexposed area of the image-recording layer is removed by supplying at least one of printing ink and dampening water on a printing machine after image exposure. Such an image-recording layer can be constructed by appropriately adjusting at least one of the kinds and amounts of the respective components of the image-recording layer.

### <Formation of Image-Recording Layer>

The image-recording layer according to the invention is formed by dispersing or dissolving each of the necessary constituting components described above in a solvent to prepare a coating solution and coating the solution. The solvent used includes, for example, 2-butanone (methyl ethyl ketone), ethylene glycol monomethyl ether, 1-methoxy-2-propanol, 2-methoxyethyl acetate, 1-methoxy-2-propyl acetate and γ-butyrolactone, but the invention should not be construed as being limited thereto. The solvents may be used individually or as a mixture. The solid content concentration of the coating solution is preferably from 1 to 50% by weight.

The coating amount (solid content) of the image-recording layer on the support after the coating and drying is preferably from 0.3 to 3.0 g/m². Various methods can be used for the coating. Examples of the method include bar coater coating, spin coating, spray coating, curtain coating, dip coating, air knife coating, blade coating and roll coating.

### [Protective Layer]

In the lithographic printing plate precursor according to the invention, a protective layer (oxygen-blocking layer) may further be provided on the image-recording layer, if desired, in order to prevent diffusion and penetration of oxygen which inhibits the polymerization reaction at the time of exposure. As a binder for the protective layer, for example, a water-soluble polymer compound relatively excellent in crystallizability is preferably used. Specifically, when polyvinyl alcohol is used as a main component, the best results can be obtained in the fundamental characteristics, for example, oxygen-blocking property and removability by development.

Polyvinyl alcohol for use in the protective layer may be partially substituted with ester, ether or acetal as long as it contains unsubstituted vinyl alcohol units for achieving the necessary oxygen-blocking property and water solubility. Also, polyvinyl alcohol may partly have other copolymer component. Polyvinyl alcohol is obtained by hydrolysis of polyvinyl acetate. As specific examples of the polyvinyl alcohol, those having a hydrolysis degree of 71 to 100% and a polymerization repeating unit number of 300 to 2,400 are exemplified. Specific examples thereof include PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613 and L-8 (produced by Kuraray Co., Ltd.). They can be used individually or as a mixture. According to a preferred embodiment, the content of polyvinyl alcohol in the protective layer is from 20 to 95% by weight, and more preferably from 30 to 90% by weight.

Also, known modified polyvinyl alcohol can be preferably used. Particularly, an acid-modified polyvinyl alcohol having a carboxylic acid group or a sulfonic acid group is preferably used. As a component used as a mixture with polyvinyl alcohol, polyvinyl pyrrolidone or a modified product thereof is preferred from the viewpoint of the oxygen-blocking property and removability by development. The content thereof is preferably from 3.5 to 80% by weight, more preferably from 10 to 60% by weight, still more preferably from 15 to 30% by weight, in the protective layer.

As other component of the protective layer, glycerin, dipropylene glycol or the like can be added in an amount corresponding to several % by weight of the binder to provide flexibility. Further, an anionic surfactant, for example, sodium alkylsulfate or sodium alkylsulfonate, an amphoteric surfactant, for example, alkylaminocarboxylate and alkylaminodicarboxylate, or a nonionic surfactant, for example, polyoxyethylene alkyl phenyl ether can be added in an amount of several % by weight of the binder.

Further, it is also preferred to incorporate an inorganic stratiform compound, for example, natural mice or synthetic mica, as described in JP-A-2005-119273 into the protective layer of the lithographic printing plate precursor according to the invention for the purpose of increasing the oxygen-blocking property and property for protecting the surface of image-recording layer. Of the inorganic stratiform compounds, fluorine based swellable synthetic mica, which is a synthetic inorganic stratiform compound, is particularly useful.

The coating amount of the protective layer is preferably in a range from 0.05 to 10 g/m² in terms of the coating amount after drying. When the protective layer contains the inorganic stratiform compound, it is more preferably in a range from 0.1 to 0.5 g/m², and when the protective layer does not contain the inorganic stratiform compound, it is more preferably in a range from 0.5 to 5 g/m².

### [Support]

The support which can be used in the lithographic printing plate precursor according to the invention is not particularly restricted as long as it is a dimensionally stable plate-like hydrophilic support. Particularly, an aluminum plate is preferred. In advance of the use of an aluminum plate, the aluminum plate is preferably subjected to a surface treatment, for example, roughening treatment or anodizing treatment. The roughening treatment of the surface of the aluminum plate is conducted by various methods and includes, for example, mechanical roughening treatment, electrochemical roughening treatment (roughening treatment of electrochemically dissolving the surface) and chemical roughening treatment (roughening treatment of chemically dissolving the surface selectively). With respect to the treatments, methods described in Paragraph Nos. [0241] to [0245] of JP-2007-206217 are preferably used.

The center line average roughness of support is preferably from 0.10 to 1.2 μm. In the range described above, good adhesion property to the image-recording layer, good printing durability and good resistance to stain are achieved.

The color density of the support is preferably from 0.15 to 0.65 in terms of the reflection density value. In the range described above, good image-forming property by preventing halation at the image exposure and good aptitude for plate inspection after development are achieved.

The thickness of the support is preferably from 0.1 to 0.6 mm, more preferably from 0.15 to 0.4 mm, and still more preferably from 0.2 to 0.3 mm.

### [Hydrophilizing Treatment of Support]

As for the lithographic printing plate precursor according to the invention, in order to increase hydrophilicity of the non-image area and to prevent printing stain, it is preferred to conduct hydrophilizing treatment of the surface of support.

The hydrophilizing treatment of the surface of support includes an alkali metal silicate treatment wherein the support is subjected to an immersion treatment or an electrolytic treatment in an aqueous solution, for example, of sodium silicate, a method of treating with potassium fluorozirconate and a method of treating with polyvinylphosphonic acid. An immersion treatment in an aqueous polyvinylphosphonic acid solution is preferably used.

### [Backcoat Layer]

After applying the surface treatment to the support or forming the undercoat layer on the support, a backcoat layer can be provided on the back surface of the support, if desired.

The backcoat layer preferably includes, for example, a coating layer comprising an organic polymer compound described in JP-A-5-45885 and a coating layer comprising a metal oxide obtained by hydrolysis and polycondensation of an organic metal compound or an inorganic metal compound described in JP-A-6-35174. Among them, use of an alkoxy compound of silicon, for example, Si(OCH₃)₄, Si(OC₂H₅)₄, Si(OC₃H₇)₄ or Si(OC₄H₉)₄ is preferred since the starting material is inexpensive and easily available.

### [Plate Making Method]

The lithographic printing plate precursor according to the invention is exposed imagewise and then subjected to development processing to prepare a lithographic printing plate. The development processing is a method of developing (on-press development) by supplying at least any of dampening water and ink on a printing machine.

The on-press development method is not particularly restricted and includes a method where the lithographic printing plate precursor is exposed with laser and then mounted on a printing machine without undergoing the development processing to perform printing and a method where the lithographic printing plate precursor is mounted on a printing machine, exposed with laser on the printing machine and subjected to printing without undergoing the development processing. After the imagewise exposure of the lithographic printing plate precursor with laser, when an aqueous component and oily ink are supplied to perform printing without undergoing the development processing step, for example, a wet development processing step, in the exposed area of the image-recording layer, the image-recording layer cured by the exposure forms the oily ink receptive area having the oleophilic surface. On the other hand, in the unexposed area, the uncured image-recording layer is removed by dissolution or dispersion with the aqueous component and/or oily ink supplied to reveal the hydrophilic surface in the area. As a result, the aqueous component adheres on the revealed hydrophilic surface and the oily ink adheres to the exposed area of the image-recording layer, whereby printing is initiated. While either the aqueous component or oily ink may be supplied at first on the surface of exposed lithographic printing plate precursor, it is preferred to supply the oily ink at first in view of preventing the aqueous component from contamination with the unexposed area of the image-recording layer. For the aqueous component and oily ink, dampening water and printing ink for conventional lithographic printing are used respectively. Thus, the lithographic printing plate precursor is subjected to the on-press development on an offset printing machine and used as it is for printing a large number of sheets.

In advance of the above-described development processing, the lithographic printing plate precursor is imagewise exposed with laser through a transparent original having a line image, a halftone dot image or the like, or imagewise exposed, for example, by scanning of laser beam based on digital data.

The wavelength of the exposure light source is preferably from 350 to 450 nm or from 750 to 1,400 nm. In case of exposing with light of 350 to 450 nm, the lithographic printing plate precursor having an image-recording layer containing a sensitizing dye having an absorption maximum in the wavelength range is used. In case of exposing with light of 750 to 1,400 nm, the lithographic printing plate precursor containing an infrared absorbing agent which is a sensitizing dye having an absorption maximum in the wavelength range is used. As the light source of 350 to 450 nm, a semiconductor laser is preferably used. As the light source of 750 to 1,400 nm, a solid laser or semiconductor laser emitting an infrared ray is preferably used. The exposure mechanism may be any of an internal drum system, an external drum system and a flat bed system.

### EXAMPLES

The present invention will be described in more detail with reference to the following examples, but the invention should not be construed as being limited thereto. With respect to the polymer compounds used in the examples, unless otherwise particularly defined, a molecular weight means a weight average molecular weight (Mw) and a ratio of repeating unit is indicated in a molar percentage.

### Examples 1 to 35 and Comparative Examples 1 to 28

### 1. Preparation of Lithographic Printing Plate Precursors (1) to (29)

### (1) Preparation of Support

An aluminum plate (material: JIS A 1050) having a thickness of 0.3 mm was subjected to a degreasing treatment at 50° C. for 30 seconds using a 10% by weight aqueous sodium aluminate solution in order to remove rolling oil on the surface thereof and then grained the surface thereof using three nylon brushes embedded with bundles of nylon bristle having a diameter of 0.3 mm and an aqueous suspension (specific gravity: 1.1 g/cm³) of pumice having a median size of 25 μm, followed by thorough washing with water. The plate was subjected to etching by immersing in a 25% by weight aqueous sodium hydroxide solution of 45° C. for 9 seconds, washed with water, then immersed in a 20% by weight nitric acid solution at 60° C. for 20 seconds, and washed with water. The etching amount of the grained surface was about 3 g/m².

Then, using an alternating current of 60 Hz, an electrochemical roughening treatment was continuously carried out on the plate. The electrolytic solution used was a 1% by weight aqueous nitric acid solution (containing 0.5% by weight of aluminum ion) and the temperature of electrolytic solution was 50° C. The electrochemical roughening treatment was conducted using a rectangular alternating current having a trapezoidal waveform such that the time TP necessary for the current value to reach the peak from zero was 0.8 msec and the duty ratio was 1:1, and using a carbon electrode as a counter electrode. A ferrite was used as an auxiliary anode. The current density was 30 A/dm² in terms of the peak value of the electric current, and 5% of the electric current flowing from the electric source was divided to the auxiliary anode. The quantity of electricity in the nitric acid electrolysis was 175 C/dm² in terms of the quantity of electricity when the aluminum plate functioned as an anode. The plate was then washed with water by spraying.

The plate was further subjected to an electrochemical roughening treatment in the same manner as in the nitric acid electrolysis above using as an electrolytic solution, a 0.5% by weight aqueous hydrochloric acid solution (containing 0.5% by weight of aluminum ion) having temperature of 50° C. and under the condition that the quantity of electricity was 50 C/dm² in terms of the quantity of electricity when the aluminum plate functioned as an anode. The plate was then washed with water by spraying.

The plate was then subjected to an anodizing treatment using as an electrolytic solution, a 15% by weight aqueous sulfuric acid solution (containing 0.5% by weight of aluminum ion) at a current density of 15 A/dm² to form a direct current anodized film of 2.5 g/m², washed with water and dried to prepare Support (1).

Thereafter, in order to ensure the hydrophilicity of the non-image area, Support (1) was subjected to silicate treatment using a 2.5% by weight aqueous sodium silicate No. 3 solution at 60° C. for 10 seconds and then was washed with water to obtain Support (2). The adhesion amount of Si was 10 mg/m². The center line average roughness (Ra) of the support was measured using a stylus having a diameter of 2 μm and found to be 0.51 μm.

### (2) Coating of Undercoat Layer

Each of Coating solutions 1 to 29 for undercoat layer having the composition shown below was coated on Support (2) obtained above and dried at 100° C. for one minute to prepare an undercoat layer. The dry coating amount of the solution for undercoat layer was 10 mg/m². The specific polymer compounds and comparative polymer compounds used are shown in Tables 4 and 5.

<Coating solutions 1 to 29 for undercoat layer>

| | |
|---|---|
| Specific polymer compound or Comparative polymer | 0.50 g |
| compound shown in Table 4 or 5 (in total) (blend ratio | |
| in case of using two kinds being shown in Table 4 or 5) | |
| Water | 500.00 g |

### (3) Coating of Image-Recording Layer

Coating solution (2) for image-recording layer shown below was coated on the support having the undercoat layer described above by a bar and dried in an oven at 70° C. for 60 seconds to form an image-recording layer having a dry coating amount of 0.6 g/m² to prepare Lithographic printing plate precursors (1) to (29) for Examples 1 to 19 and Comparison Examples 1 to 10, respectively.

<Coating solution (2) for image-recording layer>

| | |
|---|---|
| Aqueous dispersion (1) of polymer fine particle | 20.0 g |
| Infrared absorbing dye (2) having structure shown below | 0.2 g |
| Polymerization initiator (IRGACURE 250, produced by Ciba | 0.5 g |
| Specialty Chemicals, Inc.) | |
| Radical polymerizable compound (SR-399, produced by | 1.50 g |
| Sartomer Co.) | |
| Mercapto-3-triazole | 0.2 g |
| BYK 336 (produced by BYK-Chimie GmbH) | 0.4 g |
| KLUCEL M (produced by Hercules Chemical Co., Inc.) | 4.8 g |
| ELVACITE 4026 (produced by Ineos Acrylica Inc.) | 2.5 g |
| n-Propanol | 55.0 g |
| 2-Butanone | 17.0 g |

The compounds indicated using their trade names in the composition described above are shown below.

IRGACURE 250: (4-Methoxyphenyl)[4-(2-methylpropyl)phenyl]iodonium hexafluorophosphate
(75% by weight propylene carbonate solution)
SR-399: Dipentaerythritol pentaacrylate
BYK 336: Modified dimethylpolysiloxane copolymer (25% by weight xylene/methoxypropyl acetate solution)
KLUCEL M: Hydroxypropyl cellulose (2% by weight aqueous solution)
ELVACITE 4026: Highly branched polymethyl methacrylate (10% by weight 2-butanone solution)

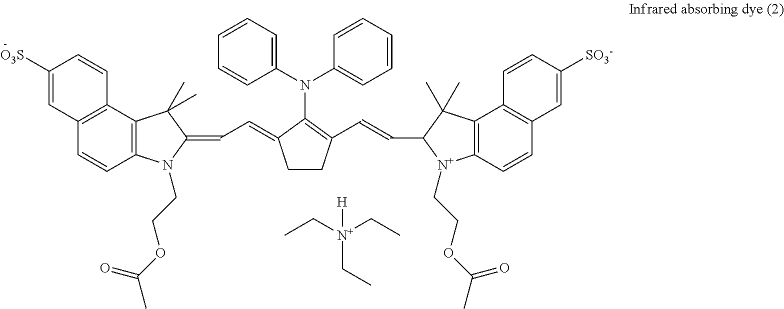

### (Preparation of Aqueous Dispersion (1) of Polymer Fine Particle)

A stirrer, a thermometer, a dropping funnel, a nitrogen inlet tube and a reflux condenser were attached to a 1,000 ml four-neck flask and while carrying out deoxygenation by introduction of nitrogen gas, 10 g of polyethylene glycol methyl ether methacrylate (PEGMA, average repeating unit number of ethylene glycol: 50), 200 g of distilled water and 200 g of n-propanol were charged therein and heated until the internal temperature reached 70° C. Then, a mixture of 10 g of styrene (St), 80 g of acrylonitrile (AN) and 0.8 g of 2,2′-azobisisobutyronitrile previously prepared was dropwise added to the flask over a period of one hour. After the completion of the dropwise addition, the mixture was continued to react as it was for 5 hours. Then, 0.4 g of 2,2′-azobisisobutyronitrile was added and the internal temperature was raised to 80° C. Thereafter, 0.5 g of 2,2′-azobisisobutyronitrile was added over a period of 6 hours. At the stage after reacting for 20 hours in total, the polymerization proceeded 98% or more to obtain Aqueous dispersion (1) of polymer fine particle of PEGMA/St/AN (10/10/80 in a weight ratio). The particle size distribution of the polymer fine particle had the maximum value at the particle size of 150 nm

The particle size distribution was determined by taking an electron microphotograph of the polymer fine particle, measuring particle sizes of 5,000 fine particles in total on the photograph, and dividing a range from the largest value of the particle size measured to 0 on a logarithmic scale into 50 parts to obtain occurrence frequency of each particle size by plotting. With respect to the aspherical particle, a particle size of a spherical particle having a particle area equivalent to the particle area of the aspherical particle on the photograph was defined as the particle size.

### 2. Preparation of Lithographic Printing Plate Precursors (40) to (49)

### (1) Coating of Image-Recording Layer

Coating solution (1) for image-recording layer having the composition shown below was coated on the undercoat layer shown in Table 6 formed as described above by a bar and dried in an oven at 100° C. for 60 seconds to form an image-recording layer having a dry coating amount of 1.0 g/m².

Coating solution (1) for image-recording layer was prepared by mixing Photosensitive solution (1) shown below with Microgel solution (1) shown below just before the coating, followed by stirring.

<Photosensitive solution (1)>

| | |
|---|---|
| Binder polymer (1) having structure shown below | 0.240 g |
| Infrared absorbing dye (1) having structure shown below | 0.030 g |
| Polymerization initiator (1) having structure shown below | 0.162 g |
| Radical polymerizable compound (Tris(acryloyloxyethyl) | 0.192 g |
| isocyanurate (NK ESTER A-9300, produced by Shin-Nakamura | |
| Chemical Co., Ltd.)) | |
| Hydrophilic low molecular weight compound | 0.062 g |
| (Tris(2-hydroxyethyl) isocyanurate) | |
| Hydrophilic low molecular weight compound (1) having | 0.050 g |
| structure shown below | |
| Oil-sensitizing agent (Phosphonium compound (1) having | 0.055 g |
| structure shown below | |
| Oil-sensitizing agent (Benzyl dimethyl octyl ammonium PF₆ | 0.018 g |
| salt) | |
| Oil-sensitizing agent (Ammonium group-containing polymer | 0.035 g |
| having structure shown below (reduced specific viscosity: 44 | |
| cSt/ml/g) | |
| Fluorine-based surfactant (1) having structure shown below | 0.008 g |
| 2-Butanone | 1.091 g |
| 1-Methoxy-2-propanol | 8.609 g |

<Microgel solution (1)>

| | |
|---|---|
| Microgel (1) | 2.640 g |
| Distilled water | 2.425 g |

The structures of Binder polymer (1), Infrared absorbing dye (1), Polymerization initiator (1), Phosphonium compound (1), Hydrophilic low molecular weight compound (1), Ammonium group-containing polymer and Fluorine-based surfactant (1) are shown below.

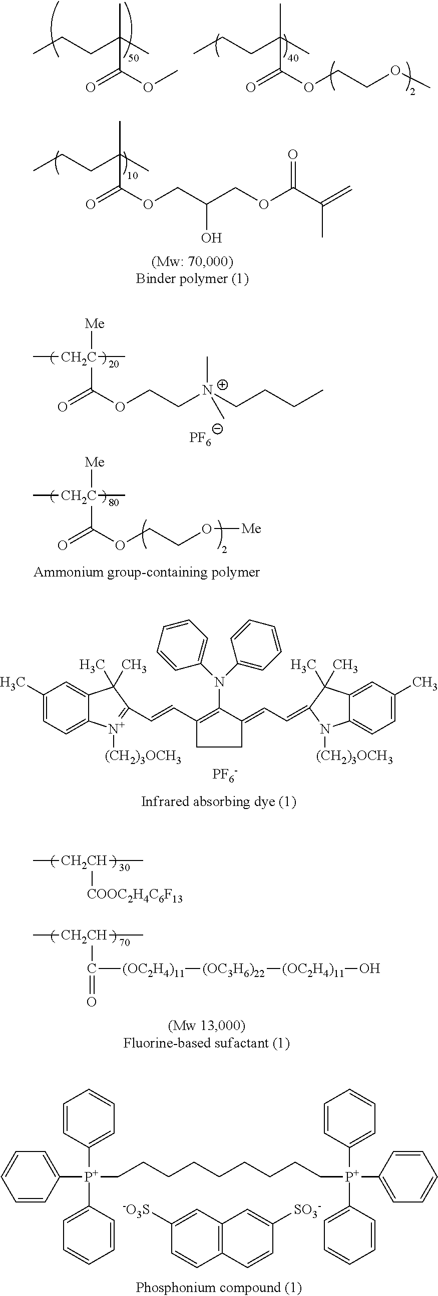

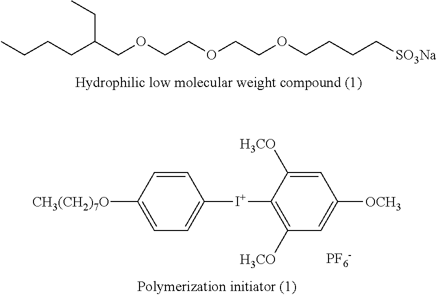

### <Preparation of Microgel (1)>

An oil phase component was prepared by dissolving 10 g of adduct of trimethylol propane and xylene diisocyanate (TAKENATE D-110N, produced by Mitsui Chemicals, Inc.), 3.15 g of pentaerythritol triacrylate (SR444, produced by Nippon Kayaku Co., Ltd.) and 0.1 g of PIONIN A-41C (produced by Takemoto Oil & Fat Co., Ltd.) in 17 g of ethyl acetate. As an aqueous phase component, 40 g of an aqueous 4% by weight solution of polyvinyl alcohol (PVA-205, produced by Kuraray Co., Ltd) was prepared. The oil phase component and the aqueous phase component were mixed and the mixture was emulsified using a homogenizer at 12,000 rpm for 10 minutes. The resulting emulsion was added to 25 g of distilled water and stirred at room temperature for 30 minutes and then at 50° C. for 3 hours. The microgel liquid thus-obtained was diluted using distilled water so as to have the solid content concentration of 15% by weight to prepare Microgel (1). The average particle size of the microgel was measured by a light scattering method and found to be 0.2

### (2) Coating of Protective Layer

Coating solution (1) for protective layer having the composition shown below was further coated on the image-recording layer described above by a bar and dried in an oven at 120° C. for 60 seconds to form a protective layer having a dry coating amount of 0.15 g/m², thereby preparing Lithographic printing plate precursors (40) to (49) for Comparative Examples 17 to 22 and Examples 24 to 27, respectively.

<Coating solution (1) for protective layer>

| | |
|---|---|
| Dispersion of inorganic stratiform compound (1) | 1.5 g |
| Aqueous 6% by weight solution of polyvinyl alcohol (CKS 50, | 0.55 g |
| sulfonic acid-modified, saponification degree: 99% by mole or | |
| more, polymerization degree: 300, produced by Nippon | |
| Synthetic Chemical Industry Co., Ltd.) | |
| Aqueous 6% by weight solution of polyvinyl alcohol (PVA-405, | 0.03 g |
| saponification degree: 81.5% by mole, polymerization degree: | |
| 500, produced by Kuraray Co., Ltd.) | |
| Aqueous 1% by weight solution of surfactant (EMALEX 710, | 0.86 g |
| produced by Nihon Emulsion Co., Ltd.) | |
| Ion-exchanged water | 6.0 g |

### <Preparation of Dispersion of Inorganic Stratiform Compound (1)>

To 193.6 g of ion-exchanged water was added 6.4 g of synthetic mica (SOMASIF ME-100, produced by CO-OP Chemical Co., Ltd.) and the mixture was dispersed using a homogenizer until an average particle size (according to a laser scattering method) became 3 μm. The aspect ratio of the inorganic particle thus-dispersed was 100 or more.

### 3. Preparation of Lithographic Printing Plate Precursors (50) to (63)

Coating solutions 30 to 33 for undercoat layer were prepared by changing the specific polymer compounds used in the preparation of Coating solutions 1 to 29 for undercoat layer to those shown in Table 8, respectively. The coating solution for undercoat layer thus-prepared was coated in the same manner as in the cases of using Coating solutions 1 to 29 for undercoat layer to form an undercoat layer.

Coating solution (3) for Image-recording layer shown below was coated on the undercoat layer shown in Table 7 or 8 formed as described above by a bar and dried in an oven at 100° C. for 60 seconds to form an image-recording layer having a dry coating amount of 1.0 g/m².

Coating solution (3) for Image-recording layer was prepared in the same manner as in Coating solution (1) for Image-recording layer except for replacing Binder polymer (1) in Photosensitive solution (1) to Binder polymer (A-1) having a branched structure.

Then, Coating solution (1) for protective layer described above was further coated on the image-recording layer described above by a bar and dried in an oven at 120° C. for 60 seconds to form a protective layer having a dry coating amount of 0.15 g/m², thereby preparing Lithographic printing plate precursors (50) to (63) for Comparative Examples 23 to 28 and Examples 28 to 35, respectively.

### 4. Evaluation of Lithographic Printing Plate Precursor

### (1) On-Press Development Property

The lithographic printing plate precursor obtained was exposed by LUXEL PLATESETTER T-6000III equipped with an infrared semiconductor laser (produced by FUJIFILM Corp.) under the conditions of a rotational number of an external drum of 1,000 rpm, laser output of 70% and resolution of 2,400 dpi. The exposed image contained a solid image and a 50% halftone dot chart of a 20 μm-dot FM screen.

The exposed lithographic printing plate precursor was mounted without undergoing development processing on a plate cylinder of a printing machine (LITHRONE 26, produced by Komori Corp.). Using dampening water (ECOLITY-2 (produced by FUJIFILM Corp.)/tap water=2/98 (by volume ratio)) and black ink (SPACE COLOR FUSION G, produced by DIC Graphics Corp.), the dampening water and ink were supplied according to the standard automatic printing start method of LITHRONE 26 to conduct printing on 100 sheets of TOKUBISHI art paper (76.5 kg) at a printing speed of 10,000 sheets per hour.

A number of the printing papers required until the on-press development of the unexposed area of the image-recording layer on the printing machine was completed to reach a state where the ink was not transferred to the printing paper in the non-image area was measured to evaluate the on-press development property. The results obtained are shown in Tables 4 to 8. The number of the printing papers of 50 sheets or less is in an acceptable level.

### (2) Printing Durability

After performing the evaluation for the on-press development property described above, the printing was continued. As the increase in a number of printing papers, the image-recording layer was gradually abraded to cause decrease in the ink density on a printed material. A number of printed materials wherein a value obtained by measuring a halftone dot area rate of the 50% halftone dot of FM screen on the printed material using a Gretag densitometer decreased by 5% from the value measured on the 100th paper of the printing was determined to evaluate the printing durability. The results obtained are shown in Tables 4 to 8. The number of the printing papers of 5×10⁴ sheets or more is in an acceptable level.

### (3) Stain Resistance

The 20th sheet of the printed material from the initiation of printing was picked up and the density of ink adhered on the non-image area was determined to evaluate the stain resistance. The stain resistance was visually evaluated and ranked on a score of 1 to 5. As the score increases, the stain resistance is better. Since it was not necessary the case that the adhesion of ink on the non-image area occurred uniform, the evaluation of stain resistance was conducted using the score of the visual observation. The results obtained are shown in Tables 4 to 8. The score of 3 or more is in an acceptable level.

(4) Stain Resistance after Lapse of Time

The lithographic printing plate obtained was stored in a temperature and humidity controlled chamber set at temperature of 60° C. and relative humidity of 60% for 3 days and then subjected to the plate making and printing in the same manner as described above. The 20th sheet of the printed material from the initiation of printing was picked up and the density of ink adhered on the non-image area was determined to evaluate the stain resistance. The stain resistance was visually evaluated and ranked on a score of 1 to 5. The criteria of the visual observation were same as those described in the stain resistance described above. As the score increases, the stain resistance is better. The results obtained are shown in Tables 4 to 8. The score of 3 or more is in an acceptable level.

TABLE 4
Comparative Examples 1 to 6 and Examples 1 to 13

| | | | | | | | | | Stain Resistance | On-press |
|---|---|---|---|---|---|---|---|---|---|---|
| | Lithographic | Coating Solution for Undercoat Layer | | | | | Printing | Stain | after Lapse | Development |
| | Printing Plate | | Specific Polymer Compound | | | | Durability | Resistance | of Time | Property |
| | Precursor | No. | (D1) | (D2) | Others | Blend Ratio | (×10⁴ sheets) | (score) | (score) | (sheets) |
| Comparative | (1) | 1 | D1-1 | | | | 2 | 5 | 5 | 20 |
| Example 1 | | | | | | | | | | |
| Comparative | (2) | 2 | D1-5 | | | | 2 | 4 | 4 | 20 |
| Example 2 | | | | | | | | | | |
| Comparative | (3) | 3 | D1-9 | | | | 2 | 4 | 4 | 20 |
| Example 3 | | | | | | | | | | |
| Comparative | (4) | 4 | | D2-1 | | | 5 | 1 | 1 | 20 |
| Example 4 | | | | | | | | | | |
| Comparative | (5) | 5 | | | R-1 | | 4.5 | 3 | 2 | 20 |
| Example 5 | | | | | | | | | | |
| Comparative | (6) | 6 | | D2-1 | R-2 | 70:30 | 5 | 2 | 1 | 20 |
| Example 6 | | | | | | | | | | |
| Example 1 | (7) | 7 | D1-1 | D2-1 | | 70:30 | 6 | 4 | 4 | 20 |
| Example 2 | (8) | 8 | D1-2 | D2-1 | | 70:30 | 6 | 4 | 4 | 20 |
| Example 3 | (9) | 9 | D1-3 | D2-1 | | 70:30 | 6 | 3 | 3 | 20 |
| Example 4 | (10) | 10 | D1-4 | D2-1 | | 70:30 | 6 | 3 | 3 | 20 |
| Example 5 | (11) | 11 | D1-5 | D2-1 | | 70:30 | 6 | 3 | 3 | 20 |
| Example 6 | (12) | 12 | D1-6 | D2-1 | | 70:30 | 6 | 3 | 3 | 20 |
| Example 7 | (13) | 13 | D1-7 | D2-1 | | 70:30 | 6 | 3 | 3 | 20 |
| Example 8 | (14) | 14 | D1-8 | D2-1 | | 70:30 | 6 | 4 | 4 | 20 |
| Example 9 | (15) | 15 | D1-9 | D2-1 | | 70:30 | 6 | 5 | 5 | 20 |
| Example 10 | (16) | 16 | D1-10 | D2-1 | | 70:30 | 5 | 5 | 4 | 20 |
| Example 11 | (17) | 17 | D1-11 | D2-1 | | 70:30 | 5 | 5 | 4 | 20 |
| Example 12 | (18) | 18 | D1-12 | D2-1 | | 70:30 | 5 | 5 | 4 | 20 |
| Example 13 | (19) | 19 | D1-13 | D2-1 | | 70:30 | 5 | 5 | 4 | 20 |

TABLE 5
Comparative Examples 7 to 10 and Examples 14 to 19

| | | Coating Solution for Undercoat Layer | | | | | | | Stain Resistance | On-press |
|---|---|---|---|---|---|---|---|---|---|---|
| | Lithographic | | Specific Polymer Compound | | | | Printing | Stain | after Lapse | Development |
| | Printing Plate | | Copolymer | Copolymer | | | Durability | Resistance | of Time | Property |
| | Precursor | No. | (D1) | (D2) | Others | Blend Ratio | (×10⁴ sheets) | (score) | (score) | (sheets) |
| Comparative | (20) | 20 | D1-1 | D2-1 | | 1:99 | 10 | 1 | 1 | 20 |
| Example 7 | | | | | | | | | | |
| Comparative | (21) | 21 | D1-1 | D2-1 | | 3:97 | 9 | 2 | 2 | 20 |
| Example 8 | | | | | | | | | | |
| Example 14 | (22) | 22 | D1-1 | D2-1 | | 5:95 | 8.5 | 3 | 3 | 20 |
| Example 15 | (23) | 23 | D1-1 | D2-1 | | 10:90 | 8 | 3 | 3 | 20 |
| Example 16 | (24) | 24 | D1-1 | D2-1 | | 30:70 | 7.5 | 4 | 4 | 20 |
| Example 17 | (25) | 25 | D1-1 | D2-1 | | 50:50 | 7 | 4 | 4 | 20 |
| Example 1 | (7) | 7 | D1-1 | D2-1 | | 70:30 | 6 | 4 | 4 | 20 |
| Example 18 | (26) | 26 | D1-1 | D2-1 | | 90:10 | 5.5 | 5 | 5 | 20 |
| Example 19 | (27) | 27 | D1-1 | D2-1 | | 95:5 | 5 | 5 | 5 | 20 |
| Comparative | (28) | 28 | D1-1 | D2-1 | | 97:3 | 3.5 | 5 | 5 | 20 |
| Example 9 | | | | | | | | | | |
| Comparative | (29) | 29 | D1-1 | D2-1 | | 99:1 | 3 | 5 | 5 | 20 |
| Example 10 | | | | | | | | | | |

TABLE 6
Comparative Examples 17 to 22 and Examples 24 to 27

| | | | | | | | | | Stain Resistance | On-press |
|---|---|---|---|---|---|---|---|---|---|---|
| | Lithographic | Coating Solution for Undercoat Layer | | | | | Printing | Stain | after Lapse | Development |
| | Printing Plate | | Specific Polymer Compound | | | | Durability | Resistance | of Time | Property |
| | Precursor | No. | (D1) | (D2) | Others | Blend Ratio | (×10⁴ sheets) | (score) | (score) | (sheets) |
| Comparative | (40) | 1 | D1-1 | | | | 3 | 5 | 5 | 20 |
| Example 17 | | | | | | | | | | |
| Comparative | (41) | 2 | D1-5 | | | | 3 | 4 | 4 | 20 |
| Example 18 | | | | | | | | | | |
| Comparative | (42) | 3 | D1-9 | | | | 3 | 4 | 4 | 20 |
| Example 19 | | | | | | | | | | |
| Comparative | (43) | 4 | | D2-1 | | | 7 | 1 | 1 | 20 |
| Example 20 | | | | | | | | | | |
| Comparative | (44) | 5 | | | R-1 | | 5 | 2 | 1 | 20 |
| Example 21 | | | | | | | | | | |
| Comparative | (45) | 6 | | D2-1 | R-2 | 70:30 | 6 | 2 | 2 | 20 |
| Example 22 | | | | | | | | | | |
| Example 24 | (46) | 7 | D1-1 | D2-1 | | 70:30 | 7 | 4 | 4 | 20 |
| Example 25 | (47) | 8 | D1-2 | D2-1 | | 70:30 | 7 | 4 | 4 | 20 |
| Example 26 | (48) | 9 | D1-3 | D2-1 | | 70:30 | 7 | 3 | 4 | 20 |
| Example 27 | (49) | 10 | D1-4 | D2-1 | | 70:30 | 7 | 3 | 4 | 20 |

TABLE 7
Comparative Examples 23 to 28 and Examples 28 to 31

| | | | | | | | | | Stain Resistance | On-press |
|---|---|---|---|---|---|---|---|---|---|---|
| | Lithographic | Coating Solution for Undercoat Layer | | | | | Printing | Stain | after Lapse | Development |
| | Printing Plate | | Specific Polymer Compound | | | | Durability | Resistance | of Time | Property |
| | Precursor | No. | (D1) | (D2) | Others | Blend Ratio | (×10⁴ sheets) | (score) | (score) | (sheets) |
| Comparative | (50) | 1 | D1-1 | | | | 3 | 5 | 5 | 20 |
| Example 23 | | | | | | | | | | |
| Comparative | (51) | 2 | D1-5 | | | | 3 | 4 | 4 | 20 |
| Example 24 | | | | | | | | | | |
| Comparative | (52) | 3 | D1-9 | | | | 3 | 4 | 4 | 20 |
| Example 25 | | | | | | | | | | |
| Comparative | (53) | 4 | | D2-1 | | | 7 | 1 | 1 | 20 |
| Example 26 | | | | | | | | | | |
| Comparative | (54) | 5 | | | R-1 | | 5 | 2 | 1 | 20 |
| Example 27 | | | | | | | | | | |
| Comparative | (55) | 6 | | D2-1 | R-2 | 70:30 | 6 | 2 | 2 | 20 |
| Example 28 | | | | | | | | | | |
| Example 28 | (56) | 7 | D1-1 | D2-1 | | 70:30 | 7 | 4 | 4 | 20 |
| Example 29 | (57) | 8 | D1-2 | D2-1 | | 70:30 | 7 | 4 | 4 | 20 |
| Example 30 | (58) | 9 | D1-3 | D2-1 | | 70:30 | 7 | 3 | 4 | 20 |
| Example 31 | (59) | 10 | D1-4 | D2-1 | | 70:30 | 7 | 3 | 4 | 20 |

TABLE 8
Examples 32 to 35

| | | | | | | | | | Stain Resistance | On-press |
|---|---|---|---|---|---|---|---|---|---|---|
| | Lithographic | Coating Solution for Undercoat Layer | | | | | Printing | Stain | after Lapse | Development |
| | Printing Plate | | Specific Polymer Compound | | | | Durability | Resistance | of Time | Property |
| | Precursor | No. | (D1) | (D2) | Others | Blend Ratio | (×10⁴ sheets) | (score) | (score) | (sheets) |
| Example 32 | (60) | 30 | D1-1 | D2-2 | | 70:30 | 7.5 | 4 | 4 | 20 |
| Example 33 | (61) | 31 | D1-1 | D2-3 | | 70:30 | 6.5 | 3 | 4 | 20 |
| Example 34 | (62) | 32 | D1-1 | D2-4 | | 70:30 | 7 | 3 | 4 | 20 |
| Example 35 | (63) | 33 | D1-14 | D2-1 | | 70:30 | 6.5 | 3 | 4 | 20 |

In Tables 4 to 8 described above, the number of specific example of the specific polymer compound (D1) in the specification is indicated in the column “(D1)”. The compounds described in the columns “(D2)” and “Others” are shown below.

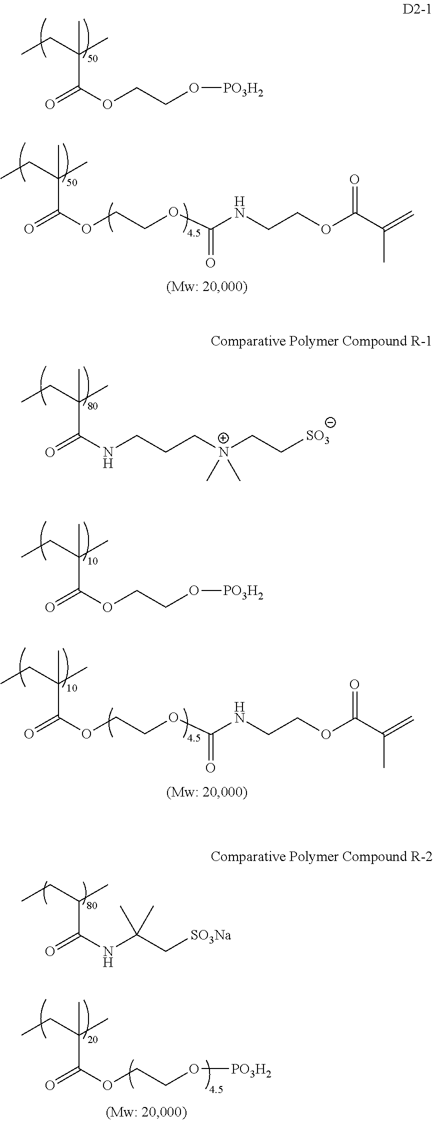

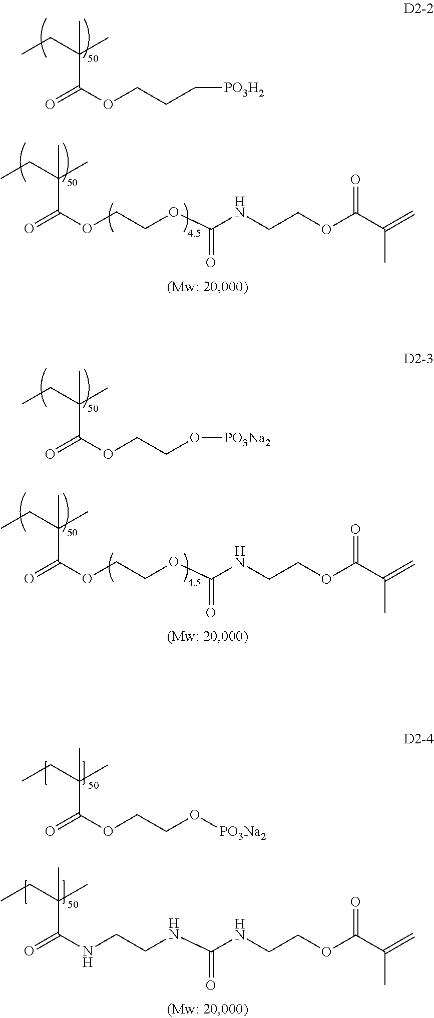

### INDUSTRIAL APPLICABILITY

According to the present invention, a lithographic printing plate precursor which exhibits high productivity capable of conducting a so-called direct plate making wherein the plate making is directly conducted based on digital signals, for example, from a computer using various kinds of lasers, can be developed on a printing machine, has high sensitivity and can provide a lithographic printing plate exhibiting good printing durability and good stain resistance (including stain resistance after the lapse of time) and a plate making method using the same can be provided.

Although the invention has been described in detail and by reference to specific embodiments, it is apparent to those skilled in the art that it is possible to add various alterations and modifications insofar as the alterations and modifications do not deviate from the spirit and the scope of the invention.

This application is based on a Japanese patent application filed on Sep. 29, 2010 (Japanese Patent Application No. 2010-220086), and the contents thereof are incorporated herein by reference.

1. A lithographic printing plate precursor comprising a support, an undercoat layer and an image-recording layer in this order, in which by exposing imagewise the image-recording layer with laser and then supplying at least any of printing ink and dampening water on a cylinder of a printing machine, an unexposed area of the image-recording layer can be removed, wherein the image-recording layer contains (A) a polymerization initiator, (B) a polymerizable compound and (C) a binder polymer, and the undercoat layer contains a copolymer (D1) having (a1) a repeating unit having a zwitterionic structure and (a2) a repeating unit having a structure capable of interacting with a surface of the support and a copolymer (D2) having (a3) a repeating unit having an ethylenically unsaturated bond and (a2) a repeating unit having a structure capable of interacting with a surface of the support and a weight of the copolymer (D1) is from 5 to 95% based on a total weight of the copolymers (D1) and (D2).

2. The lithographic printing plate precursor as claimed in claim 1, wherein the zwitterionic structure is a structure represented by the following formula (i), formula (ii) or formula (iii): 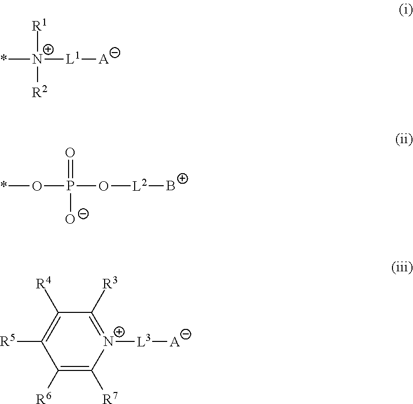
wherein, in the formula (i), the formula (ii) and the formula (iii), R¹ and R² each independently represents a hydrogen atom, an alkyl group, an alkenyl group, an alkynyl group, an aryl group or a heterocyclic group, or R¹ and R² may be combined with each other to form a ring structure, R³ to R⁷ each independently represents a hydrogen atom or a substituent, provided that at least one of R³ to R⁷ represents a site connecting to a main chain or side chain of the polymer, L¹, L² and L³ each independently represents a connecting group, A represents a group having an anion, B represents a group having a cation, and * represents a site connecting to a main chain or side chain of the polymer.

3. The lithographic printing plate precursor as claimed in claim 2, wherein in the formula (i), the formula (ii) or the formula (iii) A represents a carboxylate, a sulfonate, a phosphonate or a phosphinate, and B represents an ammonium, a phosphonium, an iodonium or a sulfonium.

4. The lithographic printing plate precursor as claimed in claim 1, wherein the structure capable of interacting with a surface of the support in at least any of the copolymer (D1) and the copolymer (D2) is a structure having a carboxylic acid group or a salt thereof, a sulfonic acid group or a salt thereof, a phosphoric ester group or a salt thereof or a phosphoric acid group or a salt thereof.

5. The lithographic printing plate precursor as claimed in claim 1, wherein the copolymer (D1) further contains (a4) a repeating unit having a hydrophilic group other than the zwitterionic structure.

6. The lithographic printing plate precursor as claimed in claim 5, wherein the hydrophilic group in the repeating unit (a4) is at least one of an alkylene oxide group, a sulfonic acid group, a sulfonate group and a sulfonamido group.

7. The lithographic printing plate precursor as claimed in claim 1, wherein the binder polymer (C) is a polymer having an alkylene oxide chain as a hydrophilic group.

8. The lithographic printing plate precursor as claimed in claim 1, wherein the binder polymer (C) is a straight-chain polymer or a branched polymer having a branch point.

9. The lithographic printing plate precursor as claimed in claim 1, which comprises a protective layer containing at least one kind of water-soluble resin as an uppermost layer.

10. A plate making method of performing on-press development processing by a method comprising exposing imagewise the lithographic printing plate precursor as claimed in claim 1, mounting the exposed lithographic printing plate precursor on a printing machine and supplying at least any of printing ink and dampening water or a method comprising mounting the lithographic printing plate precursor as claimed in claim 1 on a printing machine, exposing imagewise the lithographic printing plate precursor and supplying at least any of printing ink and dampening water.
